(19) United States
(12) Patent Application Publication
(10) Pub. No.: US 2024/0121960 A1
(43) Pub. Date: Apr. 11, 2024

(54) THREE-DIMENSIONAL MEMORY DEVICE CONTAINING DISCRETE CHARGE STORAGE ELEMENTS AND METHODS FOR FORMING THE SAME

(71) Applicant: SANDISK TECHNOLOGIES LLC, ADDISON, TX (US)

(72) Inventors: Adarsh RAJASHEKHAR, Santa Clara, CA (US); Raghuveer S. MAKALA, Campbell, CA (US); Fei ZHOU, San Jose, CA (US); Rahul SHARANGPANI, Fremont, CA (US); Kartik SONDHI, Milpitas, CA (US)

(21) Appl. No.: 18/348,702

(22) Filed: Jul. 7, 2023

Related U.S. Application Data
(60) Provisional application No. 63/378,394, filed on Oct. 5, 2022.

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A memory device includes an alternating stack of insulating layers and electrically conductive layers, a memory opening vertically extending through the alternating stack and having a lateral undulation in a vertical cross-sectional profile such that the memory opening laterally protrudes outward at levels of the electrically conductive layers, and a memory opening fill structure located in the memory opening and including a vertical stack of blocking dielectric material portions located at the levels of the electrically conductive layers, a vertical stack of discrete memory elements located at the levels of the electrically conductive layers and including a respective contoured charge storage material portion, a tunneling dielectric layer overlying the contoured inner sidewalls of the tubular charge storage material portion, and a vertical semiconductor channel.

### FIELD

The present disclosure relates generally to the field of semiconductor devices, and particularly to a three-dimensional memory device comprising discrete charge storage elements and methods for forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device is provided, which comprises: an alternating stack of insulating layers and electrically conductive layers located over a substrate; a memory opening vertically extending through the alternating stack and having a lateral undulation in a vertical cross-sectional profile such that the memory opening laterally protrudes outward at levels of the electrically conductive layers; and a memory opening fill structure located in the memory opening and comprising a vertical stack of blocking dielectric material portions locate at the levels of the electrically conductive layers, a vertical stack of discrete memory elements located at the levels of the electrically conductive layers and comprising a respective contoured charge storage material portion having a straight outer cylindrical sidewall and a contoured inner sidewall having an inner cylindrical sidewall segment, an upper annular convex sidewall segment, and a lower annular convex sidewall segment, a tunneling dielectric layer overlying the contoured inner sidewalls of the contoured charge storage material portion, and a vertical semiconductor channel.

According to another aspect of the present disclosure, a method of forming a memory device is provided, which comprises: forming an alternating stack of insulating layers and sacrificial material layers over a substrate; forming a memory opening through the alternating stack, wherein the memory opening has a lateral undulation in a vertical cross-sectional profile such that the memory opening laterally protrudes outward at levels of the sacrificial material layers; and forming a dielectric cover layer in the memory opening, wherein annular recesses are present in a vertical cross-sectional profile of a physically exposed sidewall of the dielectric cover layer; forming discrete seed material portions within the annular recesses; forming a vertical stack of charge storage material portions by selectively growing a charge storage material from physically exposed inner cylindrical sidewalls of the discrete seed material portions while suppressing growth of the charge storage material from physically exposed surfaces of the dielectric cover layer; forming a tunneling dielectric layer and a vertical semiconductor channel over the vertical stack of charge storage material portions; forming backside recesses by removing the sacrificial material layers; and forming an electrically conductive layer within each of the backside recesses.

### BRIEF DESCRIPTION OF THE DRAWINGS

FIG. 1A is a vertical cross-sectional view of an exemplary structure after formation of semiconductor devices, lower level dielectric layers, lower metal interconnect structures, and in-process source level material layers on a semiconductor substrate according to an embodiment of the present disclosure.

FIG. 1B is a top-down view of the exemplary structure of FIG. 1A. The hinged vertical plane A-A′ is the plane of the vertical cross-sectional view of FIG. 1A.

FIG. 1C is a magnified view of the in-process source level material layers along the vertical plane C-C′ of FIG. 1B.

FIG. 2 is a vertical cross-sectional view of the exemplary structure after formation of a first-tier alternating stack of first insulting layers and first spacer material layers according to an embodiment of the present disclosure.

FIG. 3 is a vertical cross-sectional view of the exemplary structure after patterning a first-tier staircase region, a first retro-stepped dielectric material portion, and an inter-tier dielectric layer according to an embodiment of the present disclosure.

FIG. 4A is a vertical cross-sectional view of the exemplary structure after formation of first-tier memory openings and first-tier support openings according to an embodiment of the present disclosure.

FIG. 4B is a horizontal cross-sectional view of the exemplary structure of FIG. 4A. The hinged vertical plane A-A′ corresponds to the plane of the vertical cross-sectional view of FIG. 4A.

FIG. 5 is a vertical cross-sectional view of the exemplary structure after formation of various sacrificial fill structures according to an embodiment of the present disclosure.

FIG. 6 is a vertical cross-sectional view of the exemplary structure after formation of a second-tier alternating stack of second insulating layers and second spacer material layers, second stepped surfaces, and a second retro-stepped dielectric material portion according to an embodiment of the present disclosure.

FIG. 7A is a vertical cross-sectional view of the exemplary structure after formation of second-tier memory openings and second-tier support openings according to an embodiment of the present disclosure.

FIG. 7B is a horizontal cross-sectional view of the exemplary structure along the horizontal plane B-B′ of FIG. 7A. The hinged vertical plane A-A′ corresponds to the plane of the vertical cross-sectional view of FIG. 7A.

FIG. 8A is a vertical cross-sectional view of the exemplary structure after formation of inter-tier memory openings and inter-tier support openings according to an embodiment of the present disclosure.

FIG. 8B is a vertical cross-sectional view of an inter-tier memory opening at the processing steps of FIG. 8A.

FIGS. 9A-9F are sequential vertical cross-sectional views of a region around an inter-tier memory opening during formation of a memory opening fill structure according to an embodiment of the present disclosure.

FIG. 10A is a vertical cross-sectional view of the exemplary structure after formation of memory opening fill structures and support pillar structures according to an embodiment of the present disclosure.

FIG. 10B is a top-down view of the exemplary structure of FIG. 10A. The hinged vertical plane A-A′ corresponds to the plane of the vertical cross-sectional view of FIG. 10A.

FIG. 10C is a vertical cross-sectional view of a memory opening fill structure in the exemplary structure of FIGS. 10A and 10B.

FIG. 11A is a vertical cross-sectional view of the exemplary structure after formation of backside trenches according to an embodiment of the present disclosure.

FIG. 11B is a horizontal cross-sectional view of the exemplary structure along the horizontal plane B-B′ of FIG. 11A. The hinged vertical plane A-A′ corresponds to the plane of the vertical cross-sectional view of FIG. 11A.

FIG. 12 is a vertical cross-sectional view of the exemplary structure after formation of backside trench spacers according to an embodiment of the present disclosure.

FIGS. 13A-13E illustrate sequential vertical cross-sectional views of memory opening fill structures and a backside trench during formation of source-level material layers according to an embodiment of the present disclosure.

FIG. 14 is a vertical cross-sectional view of the exemplary structure after formation of source-level material layers according to an embodiment of the present disclosure.

FIG. 15 is a vertical cross-sectional view of the exemplary structure after formation of backside recesses according to an embodiment of the present disclosure.

FIGS. 16A-16E are sequential vertical cross-sectional views of a region of a first configuration of the exemplary structure around a backside recess during modification of a memory opening fill structure and formation of electrically conductive layers according to a first embodiment of the present disclosure.

FIGS. 17A and 17B are sequential vertical cross-sectional views of a second configuration of the exemplary structure around a backside recess during modification of a memory opening fill structure and formation of electrically conductive layers according to a second embodiment of the present disclosure.

FIG. 18A is a vertical cross-sectional view of the exemplary structure after formation of electrically conductive layers according to an embodiment of the present disclosure.

FIG. 18B is a horizontal cross-sectional view of the exemplary structure along the horizontal plane B-B′ of FIG. 18A. The hinged vertical plane A-A′ corresponds to the plane of the vertical cross-sectional view of FIG. 18A.

FIG. 19A is a vertical cross-sectional view of the exemplary structure after formation of backside trench fill structures in the backside trenches according to an embodiment of the present disclosure.

FIG. 19B is a horizontal cross-sectional view of the exemplary structure along the horizontal plane B-B′ of FIG. 19A. The hinged vertical plane A-A′ corresponds to the plane of the vertical cross-sectional view of FIG. 19A.

FIG. 20A is a vertical cross-sectional view of the exemplary structure after formation of a second contact-level dielectric layer and various contact via structures according to an embodiment of the present disclosure.

FIG. 20B is a horizontal cross-sectional view of the exemplary structure along the vertical plane B-B′ of FIG. 20A. The hinged vertical plane A-A′ corresponds to the plane of the vertical cross-sectional view of FIG. 20A.

FIG. 21 is a vertical cross-sectional view of the exemplary structure after formation of through-memory-level via structures and upper metal line structures according to an embodiment of the present disclosure.

### DETAILED DESCRIPTION

As discussed above, the present disclosure is directed to a three-dimensional memory device comprising discrete charge storage elements and methods for forming the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

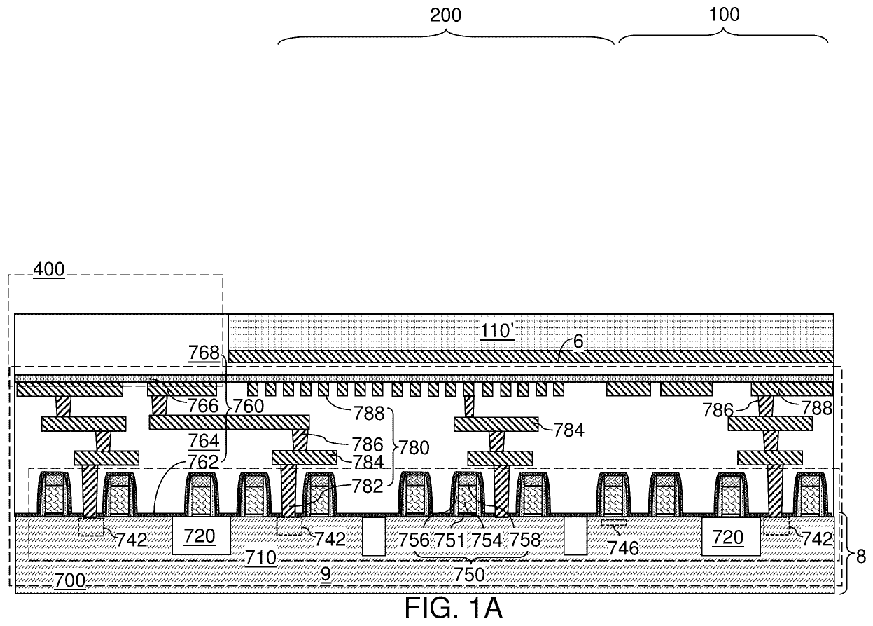

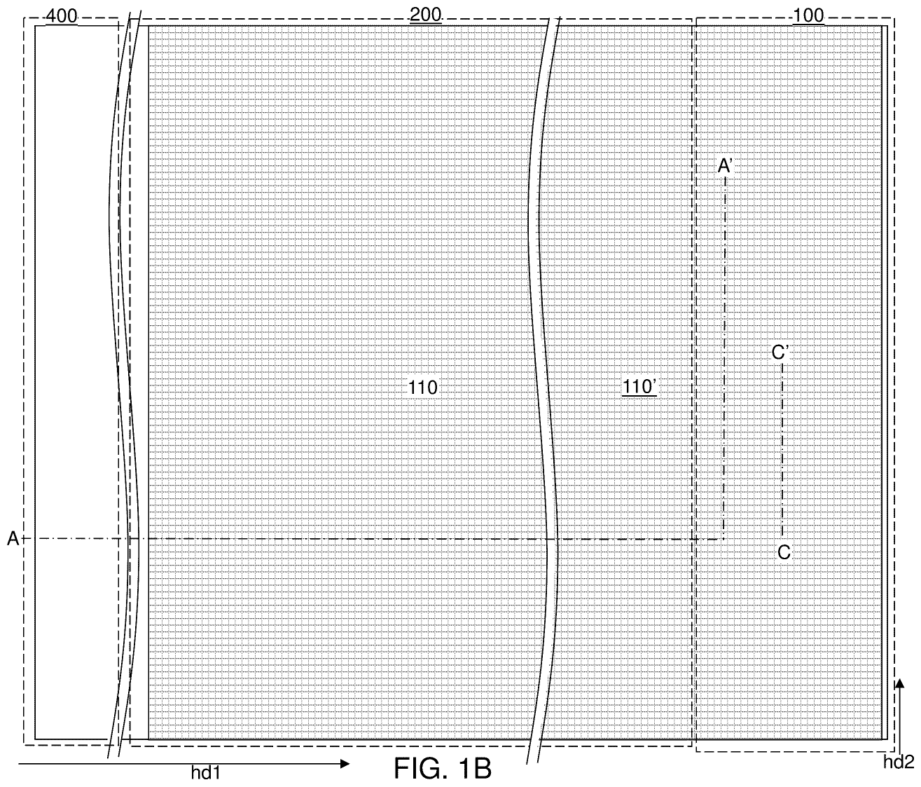

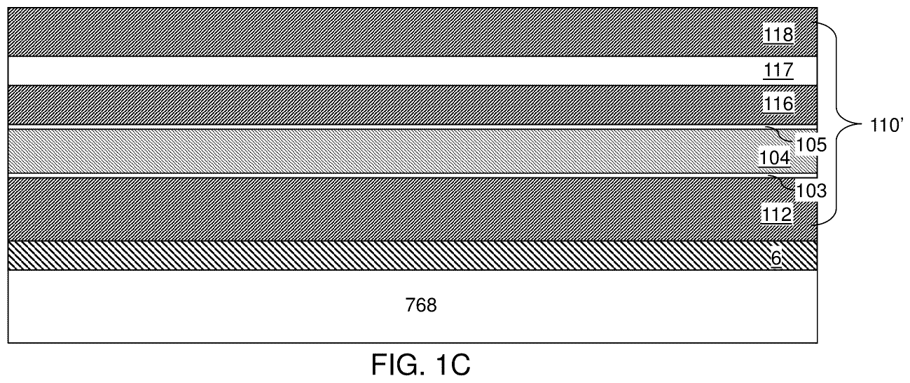

Referring to FIGS. 1A-1C, an exemplary structure according to an embodiment of the present disclosure is illustrated. FIG. 1C is a magnified view of an in-process source-level material layers 110′ illustrated in FIGS. 1A and 1B. The exemplary structure includes a substrate 8 and semiconductor devices 710 formed thereupon. The substrate 8 includes a substrate semiconductor layer 9 at least at an upper portion thereof. Shallow trench isolation structures 720 may be formed in an upper portion of the substrate semiconductor layer 9 to provide electrical isolation from other semiconductor devices. The semiconductor devices 710 may include, for example, field effect transistors including respective transistor active regions 742 (i.e., source regions and drain regions), channel regions 746, and gate structures 750. The field effect transistors may be arranged in a CMOS configuration. Each gate structure 750 may include, for example, a gate dielectric 752, a gate electrode 754, a dielectric gate spacer 756 and a gate cap dielectric 758. The semiconductor devices 710 may include any semiconductor circuitry to support operation of a memory structure to be subsequently formed, which is typically referred to as a driver circuitry, which is also known as peripheral circuitry. As used herein, a peripheral circuitry refers to any, each, or all, of word line decoder circuitry, word line switching circuitry, bit line decoder circuitry, bit line sensing and/or switching circuitry, power supply/distribution circuitry, data buffer and/or latch, or any other semiconductor circuitry that may be implemented outside a memory array structure for a memory device. For example, the semiconductor devices may include word line switching devices for electrically biasing word lines of three-dimensional memory structures to be subsequently formed.

Dielectric material layers are formed over the semiconductor devices, which are herein referred to as lower-level dielectric material layers 760. The lower-level dielectric material layers 760 may include, for example, a dielectric liner 762 (such as a silicon nitride liner that blocks diffusion of mobile ions and/or apply appropriate stress to underlying structures), first dielectric material layers 764 that overlie the dielectric liner 762, a silicon nitride layer (e.g., hydrogen diffusion barrier) 766 that overlies the first dielectric material layers 764, and at least one second dielectric layer 768.

The dielectric layer stack including the lower-level dielectric material layers 760 functions as a matrix for lower-level metal interconnect structures 780 that provide electrical wiring to and from the various nodes of the semiconductor devices and landing pads for through-memory-level contact via structures to be subsequently formed. The lower-level metal interconnect structures 780 are formed within the dielectric layer stack of the lower-level dielectric material layers 760, and comprise a lower-level metal line structure located under and optionally contacting a bottom surface of the silicon nitride layer 766.

For example, the lower-level metal interconnect structures 780 may be formed within the first dielectric material layers 764. The first dielectric material layers 764 may be a plurality of dielectric material layers in which various elements of the lower-level metal interconnect structures 780 are sequentially formed. Each dielectric material layer selected from the first dielectric material layers 764 may include any of doped silicate glass, undoped silicate glass, organosilicate glass, silicon nitride, silicon oxynitride, and dielectric metal oxides (such as aluminum oxide). In one embodiment, the first dielectric material layers 764 may comprise, or consist essentially of, dielectric material layers having dielectric constants that do not exceed the dielectric constant of undoped silicate glass (silicon oxide) of 3.9. The lower-level metal interconnect structures 780 may include various device contact via structures 782 (e.g., source and drain electrodes which contact the respective source and drain nodes of the device or gate electrode contacts), intermediate lower-level metal line structures 784, lower-level metal via structures 786, and landing-pad-level metal line structures 788 that are configured to function as landing pads for through-memory-level contact via structures to be subsequently formed.

The landing-pad-level metal line structures 788 may be formed within a topmost dielectric material layer of the first dielectric material layers 764 (which may be a plurality of dielectric material layers). Each of the lower-level metal interconnect structures 780 may include a metallic nitride liner and a metal fill structure. Top surfaces of the landing-pad-level metal line structures 788 and the topmost surface of the first dielectric material layers 764 may be planarized by a planarization process, such as chemical mechanical planarization. The silicon nitride layer 766 may be formed directly on the top surfaces of the landing-pad-level metal line structures 788 and the topmost surface of the first dielectric material layers 764.

The at least one second dielectric material layer 768 may include a single dielectric material layer or a plurality of dielectric material layers. Each dielectric material layer selected from the at least one second dielectric material layer 768 may include any of doped silicate glass, undoped silicate glass, and organosilicate glass. In one embodiment, the at least one first second material layer 768 may comprise, or consist essentially of, dielectric material layers having dielectric constants that do not exceed the dielectric constant of undoped silicate glass (silicon oxide) of 3.9.

An optional layer of a metallic material and a layer of a semiconductor material may be deposited over, or within patterned recesses of, the at least one second dielectric material layer 768, and is lithographically patterned to provide an optional conductive plate layer 6 and in-process source-level material layers 110′. The optional conductive plate layer 6, if present, provides a high conductivity conduction path for electrical current that flows into, or out of, the in-process source-level material layers 110′. The optional conductive plate layer 6 includes a conductive material such as a metal or a heavily doped semiconductor material. The optional conductive plate layer 6, for example, may include a tungsten layer having a thickness in a range from 3 nm to 100 nm, although lesser and greater thicknesses may also be used. A metal nitride layer (not shown) may be provided as a diffusion barrier layer on top of the conductive plate layer 6. The conductive plate layer 6 may function as a special source line in the completed device. In addition, the conductive plate layer 6 may comprise an etch stop layer and may comprise any suitable conductive, semiconductor or insulating layer. The optional conductive plate layer 6 may include a metallic compound material such as a conductive metallic nitride (e.g., TiN) and/or a metal (e.g., W). The thickness of the optional conductive plate layer 6 may be in a range from 5 nm to 100 nm, although lesser and greater thicknesses may also be used.

The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, a lower sacrificial liner 103, a source-level sacrificial layer 104, an upper sacrificial liner 105, an upper source-level semiconductor layer 116, a source-level insulating layer 117, and an optional source-select-level conductive layer 118.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner 103 and the upper sacrificial liner 105. In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used.

The lower sacrificial liner 103 and the upper sacrificial liner 105 include materials that may function as an etch stop material during removal of the source-level sacrificial layer 104. For example, the lower sacrificial liner 103 and the upper sacrificial liner 105 may include silicon oxide, silicon nitride, and/or a dielectric metal oxide. In one embodiment, each of the lower sacrificial liner 103 and the upper sacrificial liner 105 may include a silicon oxide layer having a thickness in a range from 2 nm to 30 nm, although lesser and greater thicknesses may also be used.

The source-level insulating layer 117 includes a dielectric material such as silicon oxide. The thickness of the source-level insulating layer 117 may be in a range from 20 nm to 400 nm, such as from 40 nm to 200 nm, although lesser and greater thicknesses may also be used. The optional source-select-level conductive layer 118 may include a conductive material that may be used as a source-select-level gate electrode. For example, the optional source-select-level conductive layer 118 may include a doped semiconductor material such as doped polysilicon or doped amorphous silicon that may be subsequently converted into doped polysilicon by an anneal process. The thickness of the optional source-select-level conductive layer 118 may be in a range from 30 nm to 200 nm, such as from 60 nm to 100 nm, although lesser and greater thicknesses may also be used.

The in-process source-level material layers 110′ may be formed directly above a subset of the semiconductor devices on the substrate 8 (e.g., silicon wafer). As used herein, a first element is located “directly above” a second element if the first element is located above a horizontal plane including a topmost surface of the second element and an area of the first element and an area of the second element has an areal overlap in a plan view (i.e., along a vertical plane or direction perpendicular to the top surface of the substrate 8.

The optional conductive plate layer 6 and the in-process source-level material layers 110′ may be patterned to provide openings in areas in which through-memory-level contact via structures and through-dielectric contact via structures are to be subsequently formed. Patterned portions of the stack of the conductive plate layer 6 and the in-process source-level material layers 110′ are present in each memory array region 100 in which three-dimensional memory stack structures are to be subsequently formed.

The optional conductive plate layer 6 and the in-process source-level material layers 110′ may be patterned such that an opening extends over a staircase region 200 in which contact via structures contacting word line electrically conductive layers are to be subsequently formed. In one embodiment, the staircase region 200 may be laterally spaced from the memory array region 100 along a first horizontal direction hd1. A horizontal direction that is perpendicular to the first horizontal direction hd1 is herein referred to as a second horizontal direction hd2. In one embodiment, additional openings in the optional conductive plate layer 6 and the in-process source-level material layers 110′ may be formed within the area of a memory array region 100, in which a three-dimensional memory array including memory stack structures is to be subsequently formed. A peripheral device region 400 that is subsequently filled with a field dielectric material portion may be provided adjacent to the staircase region 200.

The region of the semiconductor devices 710 and the combination of the lower-level dielectric material layers 760 and the lower-level metal interconnect structures 780 is herein referred to an underlying peripheral device region 700, which is located underneath a memory-level assembly to be subsequently formed and includes peripheral devices for the memory-level assembly. The lower-level metal interconnect structures 780 are formed in the lower-level dielectric material layers 760.

The lower-level metal interconnect structures 780 may be electrically connected to active nodes (e.g., transistor active regions 742 or gate electrodes 754) of the semiconductor devices 710 (e.g., CMOS devices), and are located at the level of the lower-level dielectric material layers 760. Through-memory-level contact via structures may be subsequently formed directly on the lower-level metal interconnect structures 780 to provide electrical connection to memory devices to be subsequently formed. In one embodiment, the pattern of the lower-level metal interconnect structures 780 may be selected such that the landing-pad-level metal line structures 788 (which are a subset of the lower-level metal interconnect structures 780 located at the topmost portion of the lower-level metal interconnect structures 780) may provide landing pad structures for the through-memory-level contact via structures to be subsequently formed.

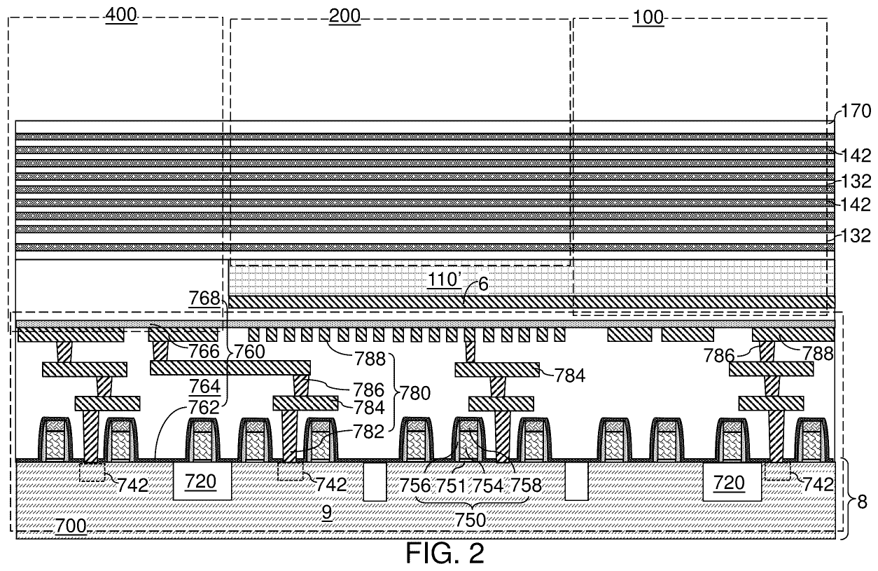

Referring to FIG. 2, an alternating stack of first material layers and second material layers is subsequently formed. Each first material layer may include a first material, and each second material layer may include a second material that is different from the first material. In case at least another alternating stack of material layers is subsequently formed over the alternating stack of the first material layers and the second material layers, the alternating stack is herein referred to as a first-tier alternating stack. The level of the first-tier alternating stack is herein referred to as a first-tier level, and the level of the alternating stack to be subsequently formed immediately above the first-tier level is herein referred to as a second-tier level, etc.

The first-tier alternating stack may include first insulting layers 132 as the first material layers, and first spacer material layers as the second material layers. In one embodiment, the first spacer material layers may be sacrificial material layers that are subsequently replaced with electrically conductive layers. In another embodiment, the first spacer material layers may be electrically conductive layers that are not subsequently replaced with other layers. While the present disclosure is described using embodiments in which sacrificial material layers are replaced with electrically conductive layers, embodiments in which the spacer material layers are formed as electrically conductive layers (thereby obviating the need to perform replacement processes) are expressly contemplated herein.

In one embodiment, the first material layers and the second material layers may be first insulating layers 132 and first sacrificial material layers 142, respectively. In one embodiment, each first insulating layer 132 may include a first insulating material, and each first sacrificial material layer 142 may include a first sacrificial material. An alternating plurality of first insulating layers 132 and first sacrificial material layers 142 is formed over the in-process source-level material layers 110′. As used herein, a “sacrificial material” refers to a material that is removed during a subsequent processing step.

As used herein, an alternating stack of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness throughout, or may have different thicknesses. The second elements may have the same thickness throughout, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

The first-tier alternating stack (132, 142) may include first insulating layers 132 composed of the first material, and first sacrificial material layers 142 composed of the second material, which is different from the first material. The first material of the first insulating layers 132 may be at least one insulating material. Insulating materials that may be used for the first insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first insulating layers 132 may be silicon oxide.

The second material of the first sacrificial material layers 142 is a sacrificial material that may be removed selective to the first material of the first insulating layers 132. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The first sacrificial material layers 142 may comprise an insulating material, a semiconductor material, or a conductive material. The second material of the first sacrificial material layers 142 may be subsequently replaced with electrically conductive electrodes which may function, for example, as control gate electrodes of a vertical NAND device. In one embodiment, the first sacrificial material layers 142 may be material layers that comprise silicon nitride.

In one embodiment, the first insulating layers 132 may include silicon oxide, and sacrificial material layers may include silicon nitride sacrificial material layers. The first material of the first insulating layers 132 may be deposited, for example, by chemical vapor deposition (CVD). For example, if silicon oxide is used for the first insulating layers 132, tetraethylorthosilicate (TEOS) may be used as the precursor material for the CVD process. The second material of the first sacrificial material layers 142 may be formed, for example, CVD or atomic layer deposition (ALD).

The thicknesses of the first insulating layers 132 and the first sacrificial material layers 142 may be in a range from 20 nm to 50 nm, although lesser and greater thicknesses may be used for each first insulating layer 132 and for each first sacrificial material layer 142. The number of repetitions of the pairs of a first insulating layer 132 and a first sacrificial material layer 142 may be in a range from 2 to 1,024, and typically from 8 to 256, although a greater number of repetitions may also be used. In one embodiment, each first sacrificial material layer 142 in the first-tier alternating stack (132, 142) may have a uniform thickness that is substantially invariant within each respective first sacrificial material layer 142.

A first insulating cap layer 170 is subsequently formed over the first-tier alternating stack (132, 142). The first insulating cap layer 170 includes a dielectric material, which may be any dielectric material that may be used for the first insulating layers 132. In one embodiment, the first insulating cap layer 170 includes the same dielectric material as the first insulating layers 132. The thickness of the first insulating cap layer 170 may be in a range from 20 nm to 300 nm, although lesser and greater thicknesses may also be used.

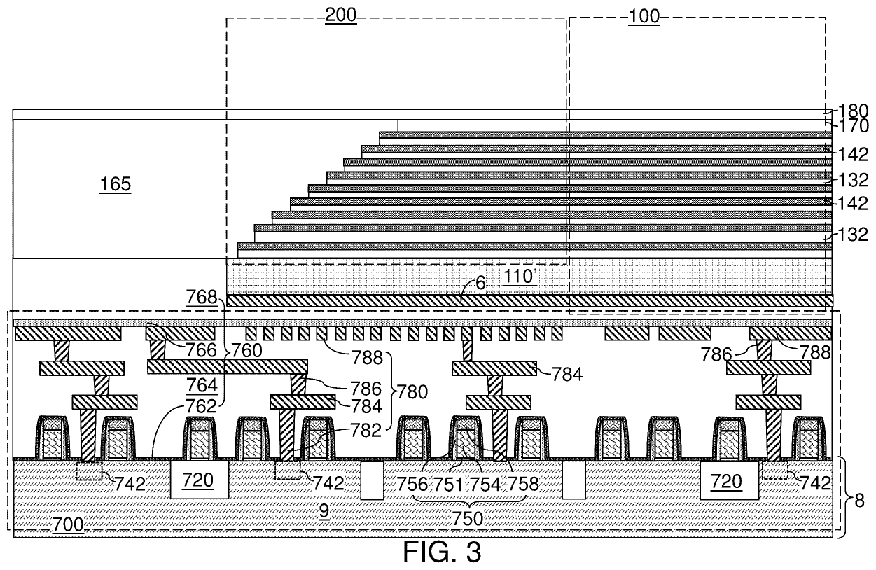

Referring to FIG. 3, the first insulating cap layer 170 and the first-tier alternating stack (132, 142) may be patterned to form first stepped surfaces in the staircase region 200. The staircase region 200 may include a respective first stepped area in which the first stepped surfaces are formed, and a second stepped area in which additional stepped surfaces are to be subsequently formed in a second-tier structure (to be subsequently formed over a first-tier structure) and/or additional tier structures. The first stepped surfaces may be formed, for example, by forming a mask layer (not shown) with an opening therein, etching a cavity within the levels of the first insulating cap layer 170, and iteratively expanding the etched area and vertically recessing the cavity by etching each pair of a first insulating layer 132 and a first sacrificial material layer 142 located directly underneath the bottom surface of the etched cavity within the etched area. In one embodiment, top surfaces of the first sacrificial material layers 142 may be physically exposed at the first stepped surfaces. The cavity overlying the first stepped surfaces is herein referred to as a first stepped cavity.

A dielectric fill material (such as undoped silicate glass or doped silicate glass) may be deposited to fill the first stepped cavity. Excess portions of the dielectric fill material may be removed from above the horizontal plane including the top surface of the first insulating cap layer 170. A remaining portion of the dielectric fill material that fills the region overlying the first stepped surfaces constitute a first retro-stepped dielectric material portion 165. As used herein, a “retro-stepped” element refers to an element that has stepped surfaces and a horizontal cross-sectional area that increases monotonically as a function of a vertical distance from a top surface of a substrate on which the element is present. The first-tier alternating stack (132, 142) and the first retro-stepped dielectric material portion 165 collectively constitute a first-tier structure, which is an in-process structure that is subsequently modified.

An inter-tier dielectric layer 180 may be optionally deposited over the first-tier structure (132, 142, 170, 165). The inter-tier dielectric layer 180 includes a dielectric material such as silicon oxide. In one embodiment, the inter-tier dielectric layer 180 may include a doped silicate glass having a greater etch rate than the material of the first insulating layers 132 (which may include an undoped silicate glass). For example, the inter-tier dielectric layer 180 may include phosphosilicate glass. The thickness of the inter-tier dielectric layer 180 may be in a range from 30 nm to 300 nm, although lesser and greater thicknesses may also be used.

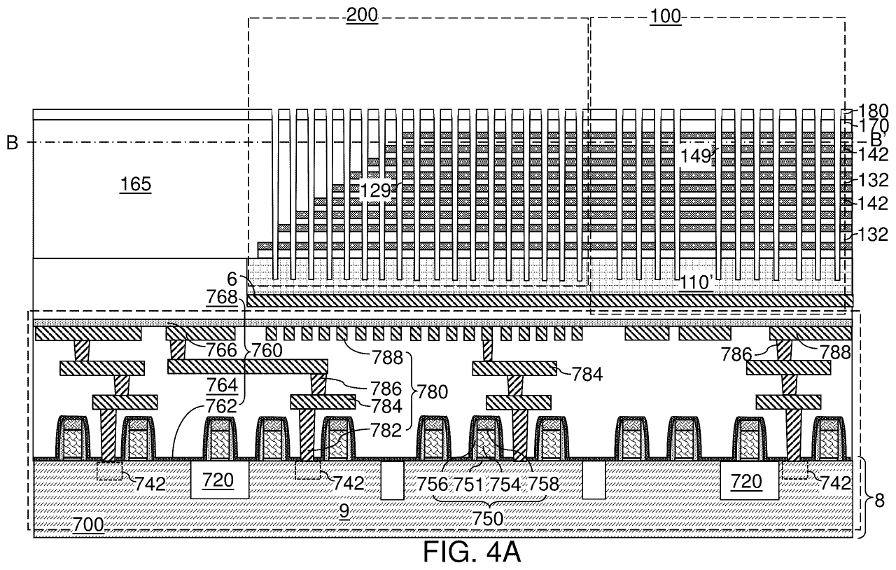

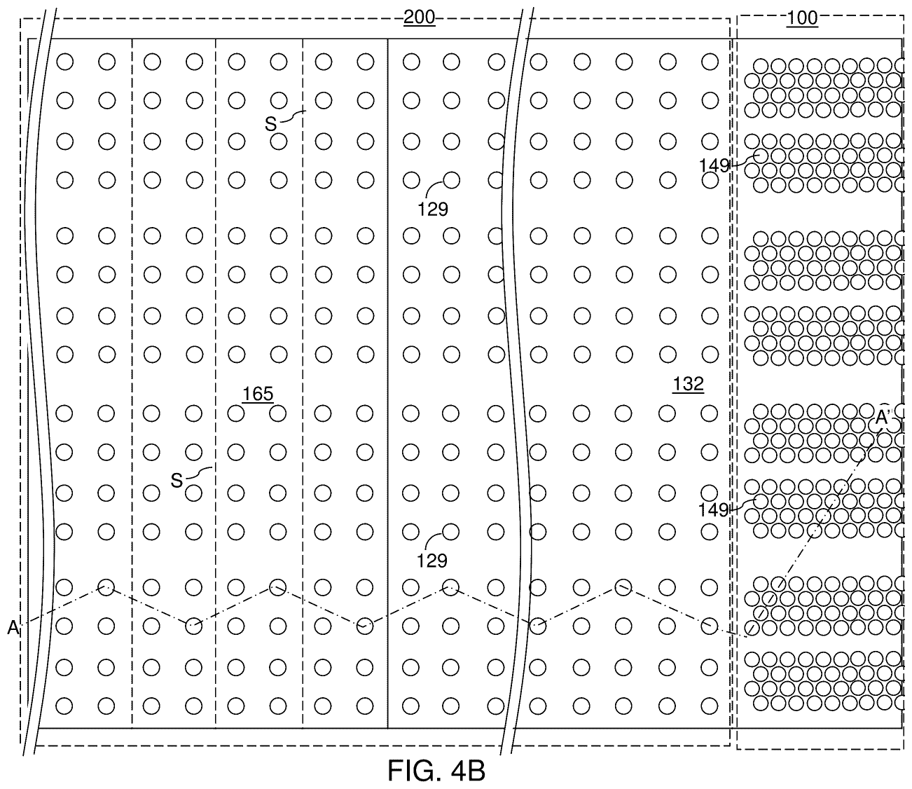

Referring to FIGS. 4A and 4B, various first-tier openings (149, 129) may be formed through the inter-tier dielectric layer 180 and the first-tier structure (132, 142, 170, 165) and into the in-process source-level material layers 110′. A photoresist layer (not shown) may be applied over the inter-tier dielectric layer 180, and may be lithographically patterned to form various openings therethrough. The pattern of openings in the photoresist layer may be transferred through the inter-tier dielectric layer 180 and the first-tier structure (132, 142, 170, 165) and into the in-process source-level material layers 110′ by a first anisotropic etch process to form the various first-tier openings (149, 129) concurrently, i.e., during the first isotropic etch process. The various first-tier openings (149, 129) may include first-tier memory openings 149 and first-tier support openings 129. Locations of steps S in the first-tier alternating stack (132, 142) are illustrated as dotted lines in FIG. 4B.

The first-tier memory openings 149 are openings that are formed in the memory array region 100 through each layer within the first-tier alternating stack (132, 142) and are subsequently used to form memory stack structures therein. The first-tier memory openings 149 may be formed in clusters of first-tier memory openings 149 that are laterally spaced apart along the second horizontal direction hd2. Each cluster of first-tier memory openings 149 may be formed as a two-dimensional array of first-tier memory openings 149.

The first-tier support openings 129 are openings that are formed in the staircase region 200, and are subsequently employed to form support pillar structures. A subset of the first-tier support openings 129 that is formed through the first retro-stepped dielectric material portion 165 may be formed through a respective horizontal surface of the first stepped surfaces.

In one embodiment, the first anisotropic etch process may include an initial step in which the materials of the first-tier alternating stack (132, 142) are etched concurrently with the material of the first retro-stepped dielectric material portion 165. The chemistry of the initial etch step may alternate to optimize etching of the first and second materials in the first-tier alternating stack (132, 142) while providing a comparable average etch rate to the material of the first retro-stepped dielectric material portion 165. The first anisotropic etch process may use, for example, a series of reactive ion etch processes or a single reaction etch process (e.g., CF₄/O₂/Ar etch). The sidewalls of the various first-tier openings (149, 129) may be substantially vertical, or may be tapered.

After etching through the alternating stack (132, 142) and the first retro-stepped dielectric material portion 165, the chemistry of a terminal portion of the first anisotropic etch process may be selected to etch through the dielectric material(s) of the at least one second dielectric layer 768 with a higher etch rate than an average etch rate for the in-process source-level material layers 110′. For example, the terminal portion of the anisotropic etch process may include a step that etches the dielectric material(s) of the at least one second dielectric layer 768 selective to a semiconductor material within a component layer in the in-process source-level material layers 110′. In one embodiment, the terminal portion of the first anisotropic etch process may etch through the source-select-level conductive layer 118, the source-level insulating layer 117, the upper source-level semiconductor layer 116, the upper sacrificial liner 105, the source-level sacrificial layer 104, and the lower sacrificial liner 103, and at least partly into the lower source-level semiconductor layer 112. The terminal portion of the first anisotropic etch process may include at least one etch chemistry for etching the various semiconductor materials of the in-process source-level material layers 110′. The photoresist layer may be subsequently removed, for example, by ashing.

Optionally, the portions of the first-tier memory openings 149 and the first-tier support openings 129 at the level of the inter-tier dielectric layer 180 may be laterally expanded by an isotropic etch. In this case, the inter-tier dielectric layer 180 may comprise a dielectric material (such as borosilicate glass) having a greater etch rate than the first insulating layers 132 (that may include undoped silicate glass) in dilute hydrofluoric acid. An isotropic etch (such as a wet etch using HF) may be used to expand the lateral dimensions of the first-tier memory openings 149 at the level of the inter-tier dielectric layer 180. The portions of the first-tier memory openings 149 located at the level of the inter-tier dielectric layer 180 may be optionally widened to provide a larger landing pad for second-tier memory openings to be subsequently formed through a second-tier alternating stack (to be subsequently formed prior to formation of the second-tier memory openings).

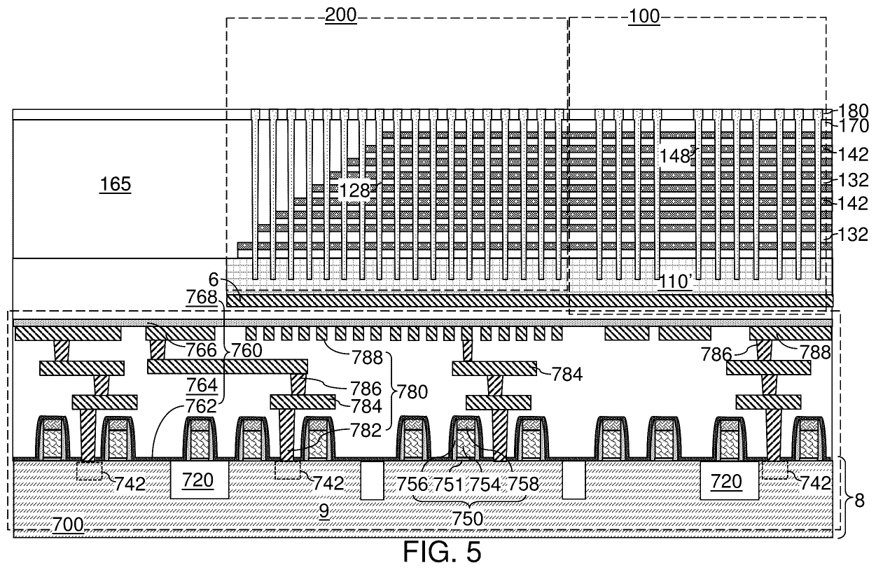

Referring to FIG. 5, sacrificial first-tier opening fill portions (148, 128) may be formed in the various first-tier openings (149, 129). For example, a sacrificial first-tier fill material is concurrently deposited in each of the first-tier openings (149, 129). The sacrificial first-tier fill material includes a material that may be subsequently removed selective to the materials of the first insulating layers 132 and the first sacrificial material layers 142.

In one embodiment, the sacrificial first-tier fill material may include a semiconductor material such as silicon (e.g., a-Si or polysilicon), a silicon-germanium alloy, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the materials of the first insulating layers 132, the first insulating cap layer 170, and the inter-tier dielectric layer 180. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In yet another embodiment, the sacrificial first-tier fill material may include amorphous silicon or a carbon-containing material (such as amorphous carbon or diamond-like carbon) that may be subsequently removed by ashing, or a silicon-based polymer that may be subsequently removed selective to the materials of the first-tier alternating stack (132, 142).

Portions of the deposited sacrificial material may be removed from above the topmost layer of the first-tier alternating stack (132, 142), such as from above the inter-tier dielectric layer 180. For example, the sacrificial first-tier fill material may be recessed to a top surface of the inter-tier dielectric layer 180 using a planarization process. The planarization process may include a recess etch, chemical mechanical planarization (CMP), or a combination thereof. The top surface of the inter-tier dielectric layer 180 may be used as an etch stop layer or a planarization stop layer.

Remaining portions of the sacrificial first-tier fill material comprise sacrificial first-tier opening fill portions (148, 128). Specifically, each remaining portion of the sacrificial material in a first-tier memory opening 149 constitutes a sacrificial first-tier memory opening fill portion 148. Each remaining portion of the sacrificial material in a first-tier support opening 129 constitutes a sacrificial first-tier support opening fill portion 128. The various sacrificial first-tier opening fill portions (148, 128) are concurrently formed, i.e., during a same set of processes including the deposition process that deposits the sacrificial first-tier fill material and the planarization process that removes the first-tier deposition process from above the first-tier alternating stack (132, 142) (such as from above the top surface of the inter-tier dielectric layer 180). The top surfaces of the sacrificial first-tier opening fill portions (148, 128) may be coplanar with the top surface of the inter-tier dielectric layer 180. Each of the sacrificial first-tier opening fill portions (148, 128) may, or may not, include cavities therein.

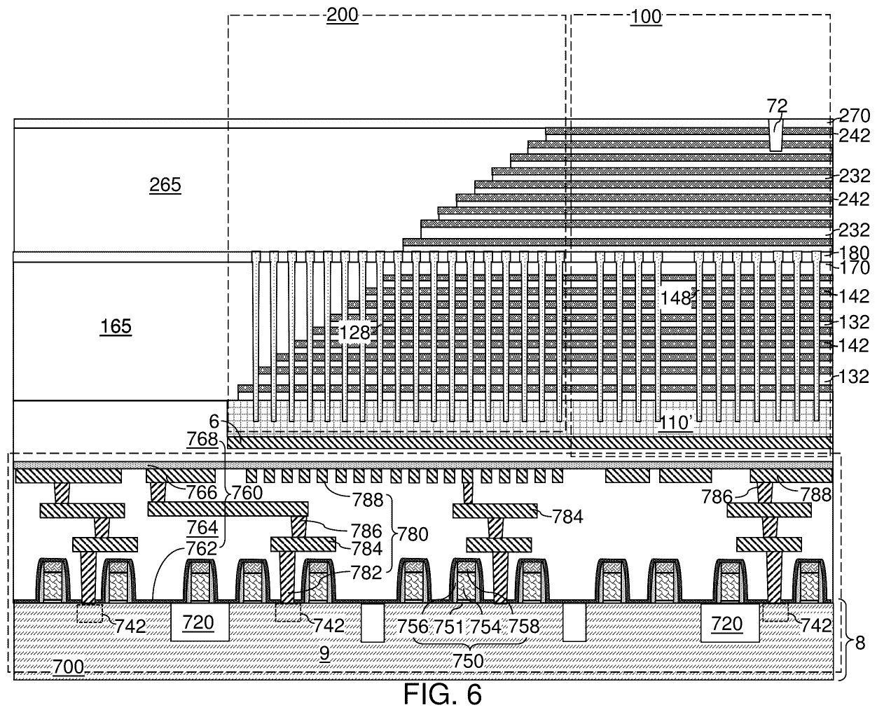

Referring to FIG. 6, a second-tier structure may be formed over the first-tier structure (132, 142, 170, 148). The second-tier structure may include an additional alternating stack of insulating layers and spacer material layers, which may be sacrificial material layers. For example, a second-tier alternating stack (232, 242) of material layers may be subsequently formed on the top surface of the first-tier alternating stack (132, 142). The second-tier alternating stack (232, 242) includes an alternating plurality of third material layers and fourth material layers. Each third material layer may include a third material, and each fourth material layer may include a fourth material that is different from the third material. In one embodiment, the third material may be the same as the first material of the first insulating layer 132, and the fourth material may be the same as the second material of the first sacrificial material layers 142.

In one embodiment, the third material layers may be second insulating layers 232 and the fourth material layers may be second spacer material layers that provide vertical spacing between each vertically neighboring pair of the second insulating layers 232. In one embodiment, the third material layers and the fourth material layers may be second insulating layers 232 and second sacrificial material layers 242, respectively. The third material of the second insulating layers 232 may be at least one insulating material. The fourth material of the second sacrificial material layers 242 may be a sacrificial material that may be removed selective to the third material of the second insulating layers 232. The second sacrificial material layers 242 may comprise an insulating material, a semiconductor material, or a conductive material. The fourth material of the second sacrificial material layers 242 may be subsequently replaced with electrically conductive electrodes which may function, for example, as control gate electrodes of a vertical NAND device.

In one embodiment, each second insulating layer 232 may include a second insulating material, and each second sacrificial material layer 242 may include a second sacrificial material. In this case, the second-tier alternating stack (232, 242) may include an alternating plurality of second insulating layers 232 and second sacrificial material layers 242. The third material of the second insulating layers 232 may be deposited, for example, by chemical vapor deposition (CVD). The fourth material of the second sacrificial material layers 242 may be formed, for example, CVD or atomic layer deposition (ALD).

The third material of the second insulating layers 232 may be at least one insulating material. Insulating materials that may be used for the second insulating layers 232 may be any material that may be used for the first insulating layers 132. The fourth material of the second sacrificial material layers 242 is a sacrificial material that may be removed selective to the third material of the second insulating layers 232. Sacrificial materials that may be used for the second sacrificial material layers 242 may be any material that may be used for the first sacrificial material layers 142. In one embodiment, the second insulating material may be the same as the first insulating material, and the second sacrificial material may be the same as the first sacrificial material.

The thicknesses of the second insulating layers 232 and the second sacrificial material layers 242 may be in a range from 20 nm to 50 nm, although lesser and greater thicknesses may be used for each second insulating layer 232 and for each second sacrificial material layer 242. The number of repetitions of the pairs of a second insulating layer 232 and a second sacrificial material layer 242 may be in a range from 2 to 1,024, and typically from 8 to 256, although a greater number of repetitions may also be used. In one embodiment, each second sacrificial material layer 242 in the second-tier alternating stack (232, 242) may have a uniform thickness that is substantially invariant within each respective second sacrificial material layer 242.

Second stepped surfaces in the second stepped area may be formed in the staircase region 200 using a same set of processing steps as the processing steps used to form the first stepped surfaces in the first stepped area with suitable adjustment to the pattern of at least one masking layer. A second retro-stepped dielectric material portion 265 may be formed over the second stepped surfaces in the staircase region 200.

A second insulating cap layer 270 may be subsequently formed over the second-tier alternating stack (232, 242). The second insulating cap layer 270 includes a dielectric material that is different from the material of the second sacrificial material layers 242. In one embodiment, the second insulating cap layer 270 may include silicon oxide. In one embodiment, the first and second sacrificial material layers (142, 242) may comprise silicon nitride.

Generally speaking, at least one alternating stack of insulating layers (132, 232) and spacer material layers (such as sacrificial material layers (142, 242)) may be formed over the in-process source-level material layers 110′, and at least one retro-stepped dielectric material portion (165, 265) may be formed over the staircase regions on the at least one alternating stack (132, 142, 232, 242).

Optionally, drain-select-level isolation structures 72 may be formed through a subset of layers in an upper portion of the second-tier alternating stack (232, 242). The second sacrificial material layers 242 that are cut by the drain-select-level isolation structures 72 correspond to the levels in which drain-select-level electrically conductive layers are subsequently formed. The drain-select-level isolation structures 72 include a dielectric material such as silicon oxide. The drain-select-level isolation structures 72 may laterally extend along a first horizontal direction hd1, and may be laterally spaced apart along a second horizontal direction hd2 that is perpendicular to the first horizontal direction hd1. The combination of the second-tier alternating stack (232, 242), the second retro-stepped dielectric material portion 265, the second insulating cap layer 270, and the optional drain-select-level isolation structures 72 collectively constitute a second-tier structure (232, 242, 265, 270, 72).

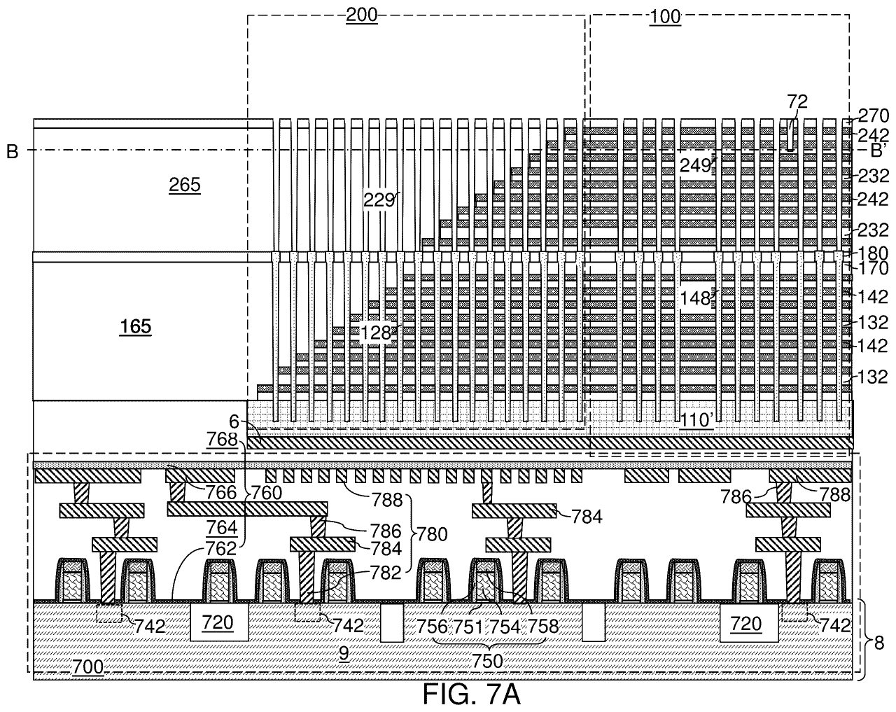

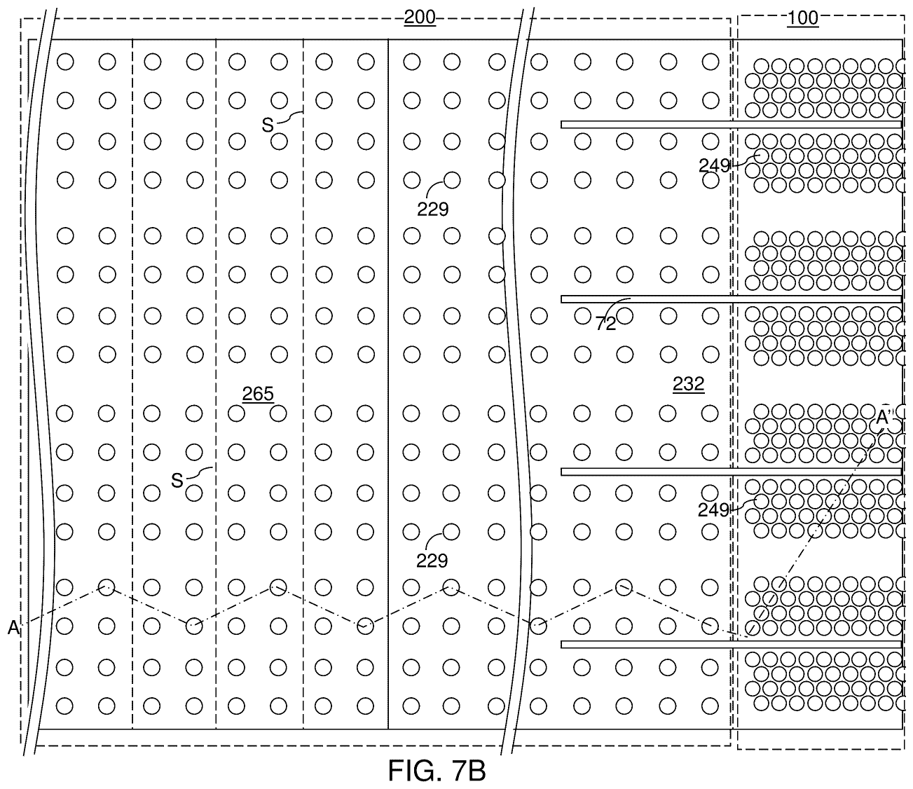

Referring to FIGS. 7A and 7B, various second-tier openings (249, 229) may be formed through the second-tier structure (232, 242, 265, 270, 72). A photoresist layer (not shown) may be applied over the second insulating cap layer 270, and may be lithographically patterned to form various openings therethrough. The pattern of the openings may be the same as the pattern of the various first-tier openings (149, 129), which is the same as the sacrificial first-tier opening fill portions (148, 128). Thus, the lithographic mask used to pattern the first-tier openings (149, 129) may be used to pattern the photoresist layer.

The pattern of openings in the photoresist layer may be transferred through the second-tier structure (232, 242, 265, 270, 72) by a second anisotropic etch process to form various second-tier openings (249, 229) concurrently, i.e., during the second anisotropic etch process. The various second-tier openings (249, 229) may include second-tier memory openings 249 and second-tier support openings 229.

The second-tier memory openings 249 are formed directly on a top surface of a respective one of the sacrificial first-tier memory opening fill portions 148. The second-tier support openings 229 are formed directly on a top surface of a respective one of the sacrificial first-tier support opening fill portions 128. Further, each second-tier support openings 229 may be formed through a horizontal surface within the second stepped surfaces, which include the interfacial surfaces between the second-tier alternating stack (232, 242) and the second retro-stepped dielectric material portion 265. Locations of steps S in the first-tier alternating stack (132, 142) and the second-tier alternating stack (232, 242) are illustrated as dotted lines in FIG. 7B.

The second anisotropic etch process may include an etch step in which the materials of the second-tier alternating stack (232, 242) are etched concurrently with the material of the second retro-stepped dielectric material portion 265. The chemistry of the etch step may alternate to optimize etching of the materials in the second-tier alternating stack (232, 242) while providing a comparable average etch rate to the material of the second retro-stepped dielectric material portion 265. The second anisotropic etch process may use, for example, a series of reactive ion etch processes or a single reaction etch process (e.g., CF₄/O₂/Ar etch). The sidewalls of the various second-tier openings (249, 229) may be substantially vertical, or may be tapered. A bottom periphery of each second-tier opening (249, 229) may be laterally offset, and/or may be located entirely within, a periphery of a top surface of an underlying sacrificial first-tier opening fill portion (148, 128). The photoresist layer may be subsequently removed, for example, by ashing.

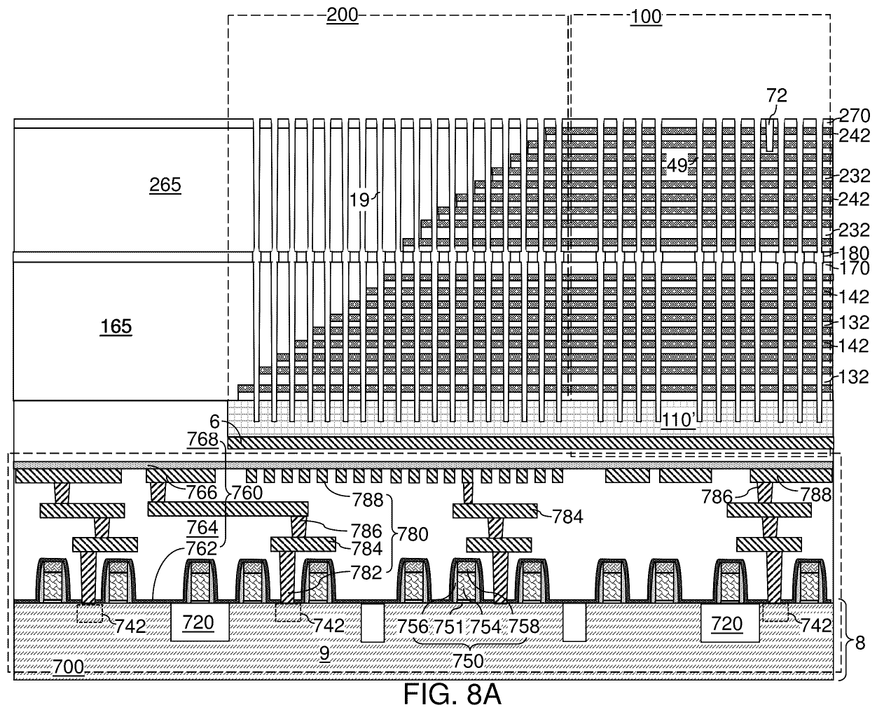

Referring to FIGS. 8A and 8B, the sacrificial first-tier fill material of the sacrificial first-tier opening fill portions (148, 128) may be removed using an etch process that etches the sacrificial first-tier fill material selective to the materials of the first and second insulating layers (132, 232), the first and second sacrificial material layers (142, 242), the first and second insulating cap layers (170, 270), and the inter-tier dielectric layer 180. A memory opening 49, which is also referred to as an inter-tier memory opening 49, is formed in each combination of a second-tier memory openings 249 and a volume from which a sacrificial first-tier memory opening fill portion 148 is removed. A support opening 19, which is also referred to as an inter-tier support opening 19, is formed in each combination of a second-tier support openings 229 and a volume from which a sacrificial first-tier support opening fill portion 128 is removed.

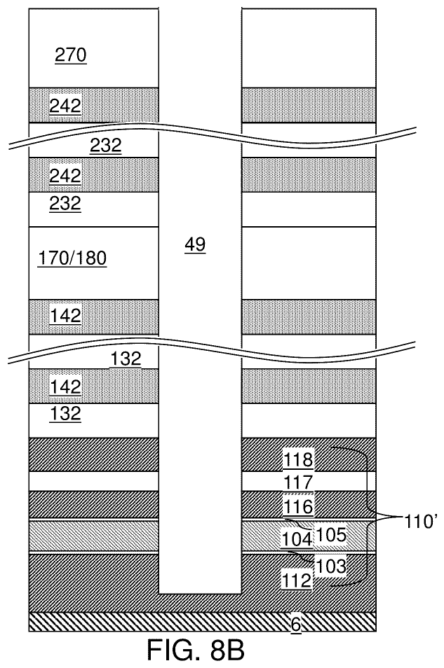

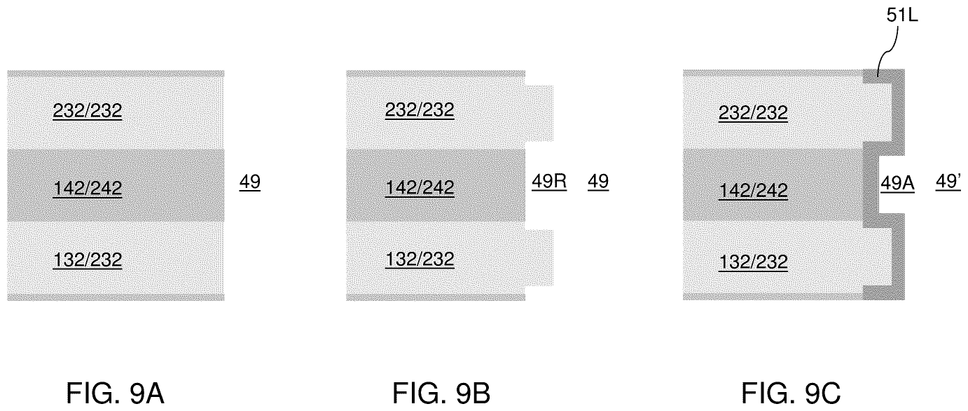

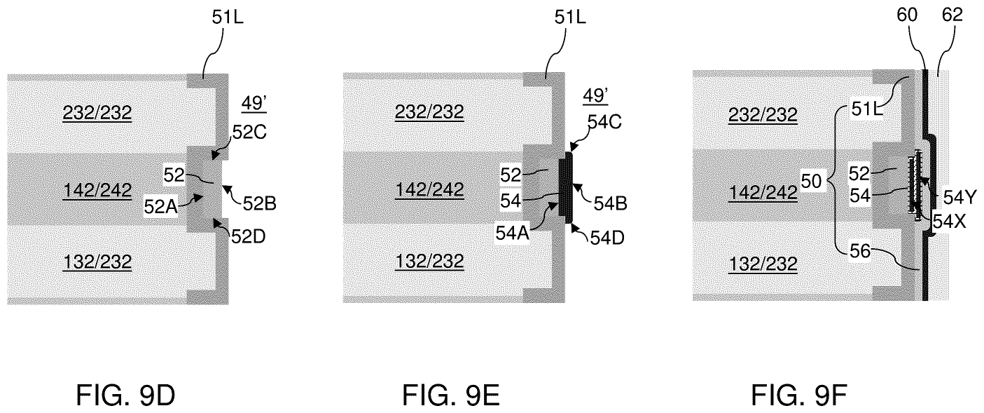

FIGS. 9A-9F provide sequential cross-sectional views of a memory opening 49 during formation of a memory opening fill structure. The same structural change occurs in each of the memory openings 49 and the support openings 19.

Referring to FIG. 9A, a portion of a memory opening 19 is illustrated at the processing steps of FIGS. 8A and 8B.

Referring to FIG. 9B, a selective isotropic etch process can be performed to isotropically etch the materials of the sacrificial material layers (142, 242) selective to the materials of the insulating layers (132, 232), the insulating cap layers (170, 270), and the inter-tier dielectric layer 180 and selective to the semiconductor materials in the in-process source-level material layers 110′ to form lateral recesses 49R in the sacrificial material layers (142, 242). For example, the sacrificial material layers (142, 242) may comprise silicon nitride, and the insulating layers (132, 232), the insulating cap layers (170, 270), and the inter-tier dielectric layer 180 may comprise silicon oxide. In this case, the selective isotropic etch process may comprise a wet etch process employing phosphoric acid. The lateral recess distance of the selective isotropic etch process, as measured between a vertical plane including sidewalls of the sacrificial material layers (142, 242) and a vertical plane including sidewalls of the insulating layers (132, 232), may be in a range from 5 nm to 50 nm, such as from 10 nm to 25 nm, although lesser and greater lateral recess distances may also be employed. Each memory opening 49 vertically extends through an alternating stack {(132, 142), (232, 242)} of insulating layers (132, 232) and sacrificial material layers (142, 242), and has a lateral undulation in a vertical cross-sectional profile such that the memory opening 49 laterally protrudes outward at levels of the electrically conductive layers (146, 246).

Referring to FIG. 9C, a dielectric cover layer 51L can be conformally deposited in the memory openings 49 and the support openings 19. The dielectric cover layer 51L comprises a dielectric material such as silicon oxynitride, carbon-doped silicon oxynitride (e.g., silicon oxycarbonitride), or silicon oxide. In one embodiment, the dielectric cover layer 51L may be deposited by a conformal deposition process, such as a chemical vapor deposition process. The thickness of the dielectric cover layer 51L may be in a range from 1 nm to 10 nm, such as from 2 nm to 6 nm, although lesser and greater thicknesses may be employed. The thickness of the dielectric cover layer 51L can be less than one half of the thickness of the sacrificial material layers (142, 242). In this case, annular recesses 49A can be present in a vertical cross-sectional profile of a physically exposed sidewall (i.e., the inner sidewall) of the dielectric cover layer 51L located within the lateral recesses 49R within each memory opening 49. A memory cavity 49′, which comprises an unfilled volume of a memory opening 49, can be present in the memory opening 49.

Each dielectric cover layer 51L continuously extends through each layer within the alternating stack {(132, 142), (232, 242)} of the insulating layers (132, 232) and the sacrificial material layers (142, 242). The dielectric cover layer 51L comprises dielectric material portions having a respective tubular configuration located at levels of the sacrificial material layers (142, 242).

Referring to FIG. 9D, a seed material from which a charge storage material may be selectively grown can be deposited in the annular recesses 49A of each memory opening 49. For example, the seed material may comprise silicon nitride or silicon (which may comprise amorphous silicon or polycrystalline silicon). The seed material can be conformally deposited by a conformal deposition process, such as a chemical vapor deposition with a thickness that is greater than a lateral recess distance of the annular recesses 49A (i.e., the lateral distance between a vertical plane including recessed sidewall segments of the dielectric cover layer 51L and a vertical plane including unrecessed sidewall segments of the dielectric cover layer 51L). An anisotropic etch process can be performed to remove portions of the seed material that are not masked by an overlying portion of the dielectric cover layer 51L. Each remaining tubular portion of the seed material constitutes a discrete seed material portion 52.

Each discrete seed material portion 52 may have a tubular configuration, and may be formed directly on an inner cylindrical sidewall of an outwardly laterally protruding portion of a dielectric cover layer 51L that is located at a level of a sacrificial material layer (142, 242). In one embodiment, each discrete seed material portion 52 may have an outer cylindrical sidewall 52A, an inner cylindrical sidewall 52B, a top annular surface 52C connecting a top periphery of the outer cylindrical sidewall and a top periphery of the inner cylindrical sidewall, and a bottom annular surface 52D connecting a bottom periphery of the outer cylindrical sidewall and a bottom periphery of the inner cylindrical sidewall. The inner cylindrical sidewall 52B of the discrete seed material portions 52 may be located within a vertical plane including the unrecessed cylindrical surface segments of the dielectric cover layer 51L. Alternatively, the inner cylindrical sidewall 52B of the discrete seed material portions 52 may be laterally offset outward from a vertical plane including the unrecessed cylindrical surface segments of the dielectric cover layer 51L by a lateral offset distance, which may be in a range from 1 nm to 20 nm. The lateral thickness of the discrete seed material portions 52, as measured between an inner cylindrical sidewall and an outer cylindrical sidewall, may be in a range from 2 nm to 40 nm, such as from 4 nm to 20 nm, although lesser and greater lateral thicknesses may also be employed.

Referring to FIG. 9E and according to an aspect of the present disclosure, a selective deposition process can be performed to grow a charge storage material from the physically exposed surfaces of the discrete seed material portions 52 while growth of the charge storage material from surfaces of the dielectric cover layer 51L is suppressed. Charge storage material portions 54 are formed directly on inner sidewalls of the discrete seed material portions 52. Generally, the charge storage material portions 54 may have the same material composition as, or may have a different material composition from, the discrete seed material portions 52.

As used herein, a selective deposition process refers to a process in which a material is grown from a first type surface while growth of the material from a second type surface is suppressed. In a non-limiting illustrative selective deposition process, a reactant gas and an etchant gas may be simultaneously or alternately flowed into a process chamber including the first type surface and the second type surface. The nucleation rate of the material derived from decomposition of the reactant gas is greater on the first type surface than on the second type surface. By selecting the flow rate of the etchant gas such that the etch rate provided by the etchant gas is greater than the nucleation rate of the material on the second type surface and is less than the nucleation rate of the material of the first type surface, the material can be grown only from the first type surface, while growth of the material from the second type surface is suppressed. Alternatively, in case the second type surface has a long incubation time for nucleation of the material, an etchant may not be necessary for the selective deposition process. The selective deposition process may comprise atomic layer deposition or chemical vapor deposition.

In one embodiment, the charge storage material comprises a non-metallic charge trapping material such as silicon nitride or silicon. In this case, a chemical vapor deposition process employing a reactant for silicon or silicon nitride may be employed with or without an etchant. In case silicon is employed for the charge storage material, the reactant gas may comprise silane, dichlorosilane, disilane, etc., and the etchant may comprise gas phase hydrochloric acid. In case silicon nitride is employed for the charge storage material, the reactant gas may comprise a combination of silane and ammonia, dichlorosilane and ammonia, etc., and the etchant, if employed, may comprise nitrogen trifluoride that is flowed alternately with the reactant gas.

In another embodiment, the charge storage material comprises a metallic material that grows from surfaces of silicon or silicon nitride while growth from silicon oxide-based surfaces of the dielectric layer 51L is suppressed. In one embodiment, the charge storage material comprises a metal, such as ruthenium, which grows from silicon nitride surfaces and does not grow from silicon oxide surfaces, during atomic layer deposition. Alternatively, the metal comprises tungsten which can be selectively grown by conversion of silicon.

Generally, a vertical stack of charge storage material portions 54 can be formed within each memory opening 49 by selectively growing a charge storage material (such as silicon, silicon nitride, or a metallic (e.g., metal) material) from physically exposed inner cylindrical sidewalls of the discrete seed material portions 52 while suppressing growth of the charge storage material from physically exposed surfaces of the dielectric cover layer 51L.

In one embodiment, the charge storage material portions 54 may have a respective contoured inner sidewall and are referred to herein to as contoured charge storage material portions 54. Specifically, the charge storage material of the contoured charge storage material portions 54 can grow isotropically from the physically exposed surfaces (i.e., the inner cylindrical sidewalls) of the discrete seed material portions 52. Thus, while the outer sidewall 54A of each contoured charge storage material portion 54 may be a vertical surface, the physically exposed inner sidewall of each contoured charge storage material portion 54 may be formed as a contoured surface including vertically straight surface segments 54B and two contoured surface segments (54C, 54D) having a respective contoured (e.g., curved convex) vertical cross-sectional profile. Thus, each contoured charge storage material portion 54 may have a straight outer cylindrical sidewall 54A and a contoured inner sidewall having an inner cylindrical sidewall segment 54B located between an upper annular convex sidewall segment 54C and a lower annular convex sidewall segment 54D.

In one embodiment, the dielectric cover layer 51L comprise a silicon oxide containing material, such as silicon dioxide, silicon oxynitride or silicon oxycarbonitride. In one embodiment, the discrete seed material portions 52 comprise silicon nitride or silicon. In one embodiment, the contoured charge storage material portions 54 comprise and/or consist essentially of a material selected from ruthenium, tungsten, silicon nitride, or silicon. Thus, the discrete seed material portions 52 may comprise the same material as or a different material than the contoured charge storage material portions 54.

The dielectric cover layer 51L vertically extends continuously through each sacrificial material layer (142, 242) within the alternating stack {(132, 142), (232, 242)}. In one embodiment, each discrete seed material portion 52 may have a straight inner sidewall 52B contacting a straight outer cylindrical sidewall 54A of a respective contoured charge storage material portion 54.

In one embodiment shown in FIG. 9F, the contoured charge storage material portion has a “mushroom” shape, and comprises an outer “stem” portion 54X having a first height and an inner “head” portion 54Y having a second height greater than the first height. As used herein, the height is the direction perpendicular to the top surface of the substrate 8. The outer “stem” portion 54X contains the straight outer cylindrical sidewall 54A. The inner “head” portion 54Y contains the inner cylindrical sidewall segment 54B, the upper annular convex sidewall segment 54C and the lower annular convex sidewall segment 54D.

Referring to FIG. 9F, a tunneling dielectric layer 56 can be conformally deposited on the vertical stack of charge storage material portions 54 and the physically exposed surfaces of the dielectric cover layer 51L. The tunneling dielectric layer 56 includes a dielectric material through which charge tunneling may be performed under suitable electrical bias conditions. The charge tunneling may be performed through hot-carrier injection or by Fowler-Nordheim tunneling induced charge transfer depending on the mode of operation of the three-dimensional NAND string memory device to be formed. The tunneling dielectric layer 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the tunneling dielectric layer 56 may include a stack of a first silicon oxide layer, a silicon oxynitride layer, and a second silicon oxide layer, which is commonly known as an ONO stack. In one embodiment, the tunneling dielectric layer 56 may include a silicon oxide layer that is substantially free of carbon or a silicon oxynitride layer that is substantially free of carbon. The thickness of the tunneling dielectric layer 56 may be in a range from 2 nm to 20 nm, although lesser and greater thicknesses may also be used.

Each combination of the dielectric cover layer 51L, a vertical stack of discrete seed material portions 52, a vertical stack of contoured charge storage material portions 54, and a tunneling dielectric layer 56 in a memory opening constitutes a memory film 50.

A vertical semiconductor channel 60 can be subsequently formed on the tunneling dielectric layer 56 in each memory opening 49. The vertical semiconductor channel 60 includes a semiconductor material having a doping of a first conductivity type. Non-limiting examples of the semiconductor material that may be employed for the vertical semiconductor channel 60 include at least one elemental semiconductor material, at least one III-V compound semiconductor material, at least one II-VI compound semiconductor material, at least one organic semiconductor material, or other semiconductor materials known in the art. In one embodiment, the vertical semiconductor channel 60 may having a uniform doping. In one embodiment, the vertical semiconductor channel 60 has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the vertical semiconductor channel 60 includes, and/or consists essentially of, boron-doped amorphous silicon or boron-doped polysilicon. In another embodiment, the vertical semiconductor channel 60 has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The vertical semiconductor channel 60 may be formed by a conformal deposition method such as low pressure chemical vapor deposition (LPCVD). The thickness of the vertical semiconductor channel 60 may be in a range from 2 nm to 10 nm, although lesser and greater thicknesses may also be used. A cavity may be present in the volume of each memory opening 49 that is not filled with the memory film 50 and the vertical semiconductor channel 60.

In case the cavity in each memory opening is not completely filled by the vertical semiconductor channel 60, a dielectric core layer may be deposited in the cavity 49′ to fill any remaining portion of the cavity 49′ within each memory opening. The dielectric core layer includes a dielectric material such as silicon oxide or organosilicate glass. The dielectric core layer may be deposited by a conformal deposition method such as low pressure chemical vapor deposition (LPCVD), or by a self-planarizing deposition process such as spin coating. The horizontal portion of the dielectric core layer overlying the second insulating cap layer 270 may be removed, for example, by a recess etch. The recess etch continues until top surfaces of the remaining portions of the dielectric core layer are recessed to a height between the top surface of the second insulating cap layer 270 and the bottom surface of the second insulating cap layer 270. Each remaining portion of the dielectric core layer constitutes a dielectric core 62.

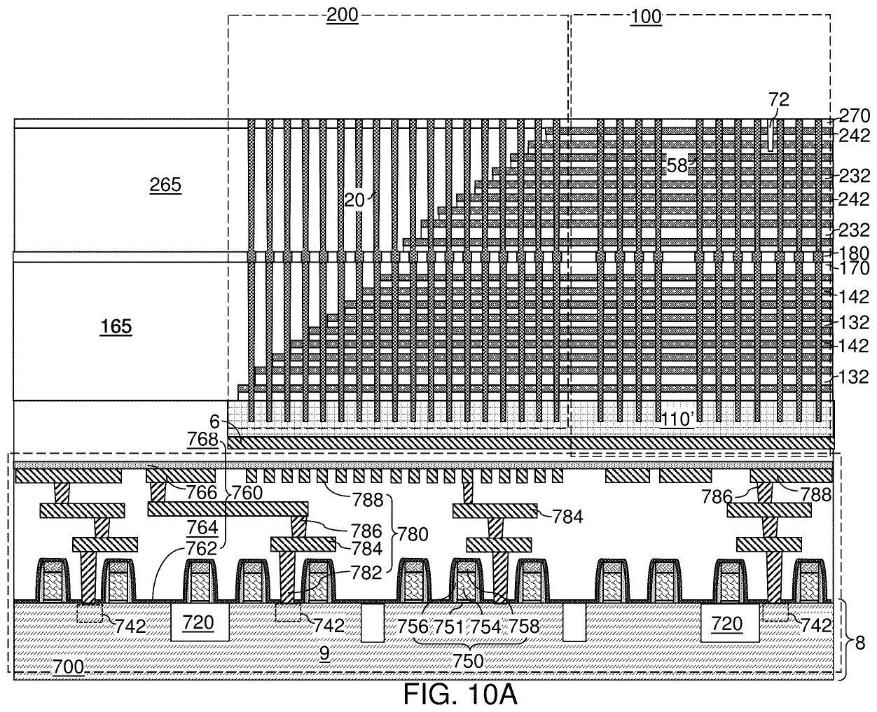

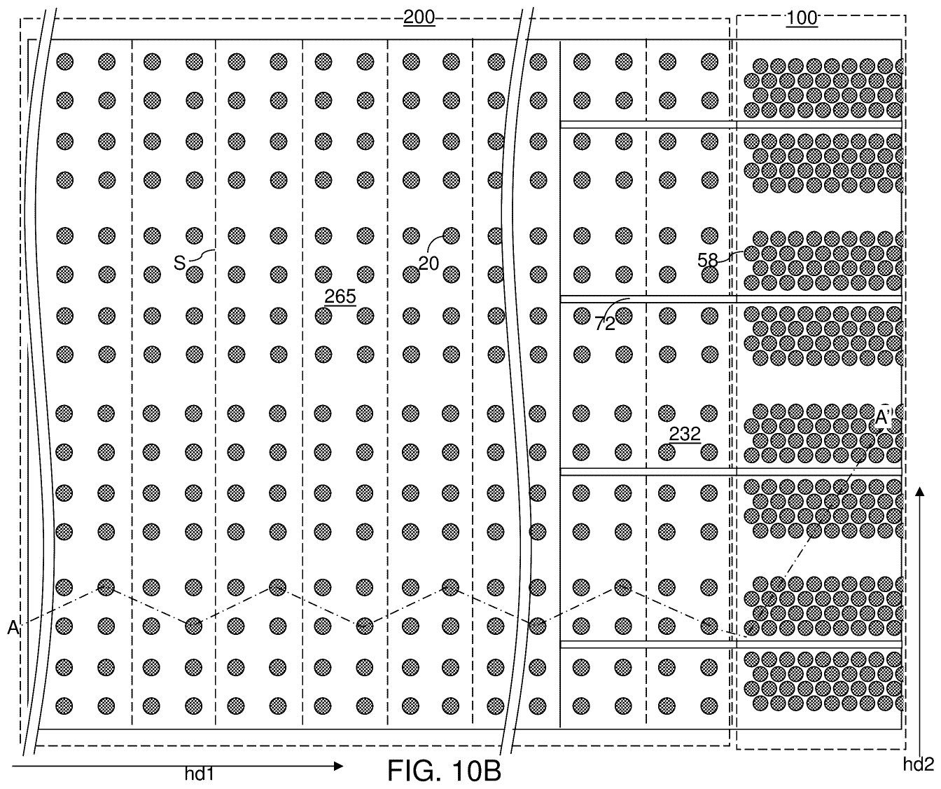

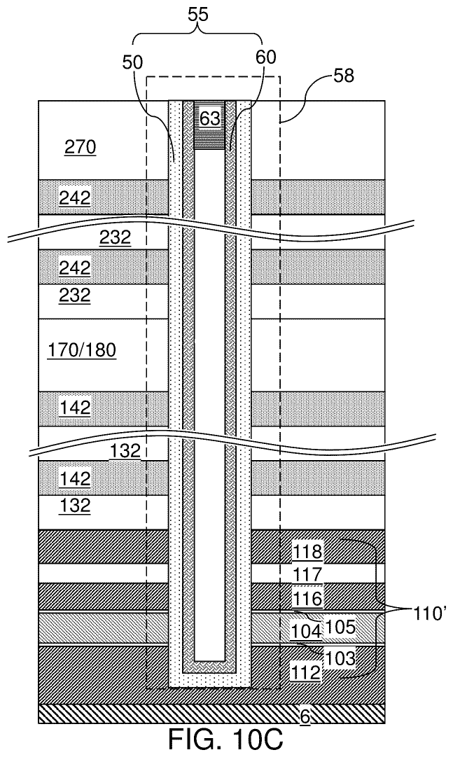

Referring to FIGS. 10A-10C, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the vertical semiconductor channel 60 and the memory film 50 that overlie the horizontal plane including the top surface of the second insulating cap layer 270 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped poly silicon.

Each memory film 50 comprises a vertical stack of discrete memory elements configured to store electrical charges with a macroscopic retention time. As used herein, a macroscopic retention time refers to a retention time suitable for operation of a memory device as a permanent memory device such as a retention time in excess of 24 hours. In some embodiments, each discrete memory element comprises a combination of a discrete seed material portion 52 and a contoured charge storage material portion 54. In this case, the discrete seed material portion 52 is referred to as a tubular charge storage material portion. In some other embodiments, the discrete seed material portions 52 are subsequently removed, and each discrete memory element consists of just the contoured charge storage material portion 54. The discrete memory elements are vertically separated from each other and do not contact each other. The discrete memory elements may comprise a discrete charge storage region (e.g., a silicon nitride charge trap element) or a floating gate (e.g., silicon or ruthenium or tungsten floating gate) of a respective memory cell.

Each combination of a memory film 50 and a vertical semiconductor channel 60 within a memory opening 49 constitutes a memory stack structure 55. Each combination of a memory stack structure 55, a dielectric core 62, and a drain region 63 within a memory opening 49 constitutes a memory opening fill structure 58. Each combination of a memory stack structure 55, a dielectric core 62, and a drain region 63 within a support opening 19 constitutes a support pillar structure 20. The in-process source-level material layers 110′, the first-tier structure (132, 142, 170, 165), the second-tier structure (232, 242, 270, 265, 72), the inter-tier dielectric layer 180, the memory opening fill structures 58, and support pillar structures 20 that are formed in the support openings 19 collectively constitute a memory-level assembly.

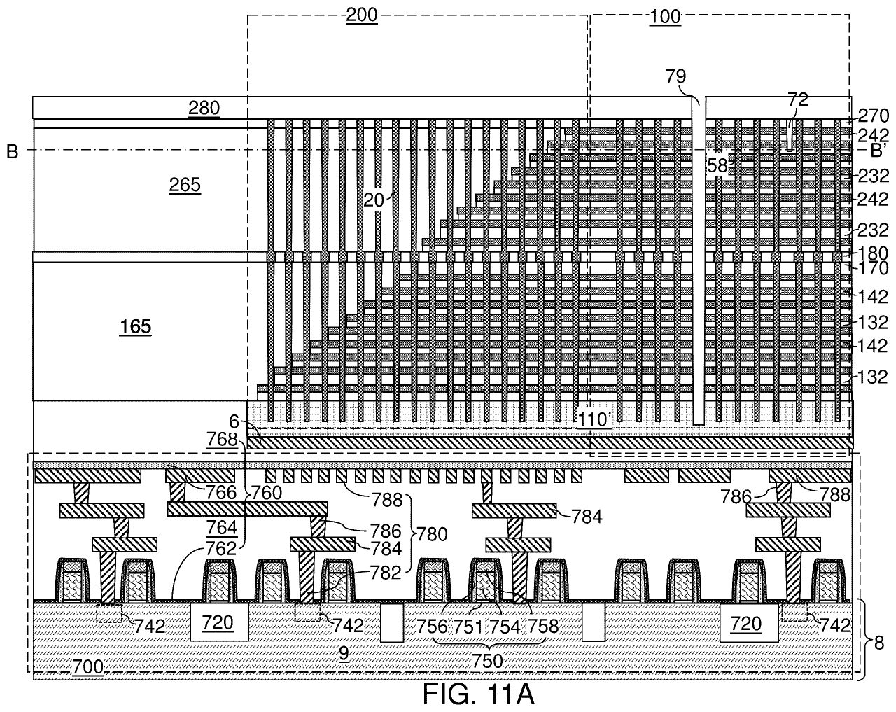

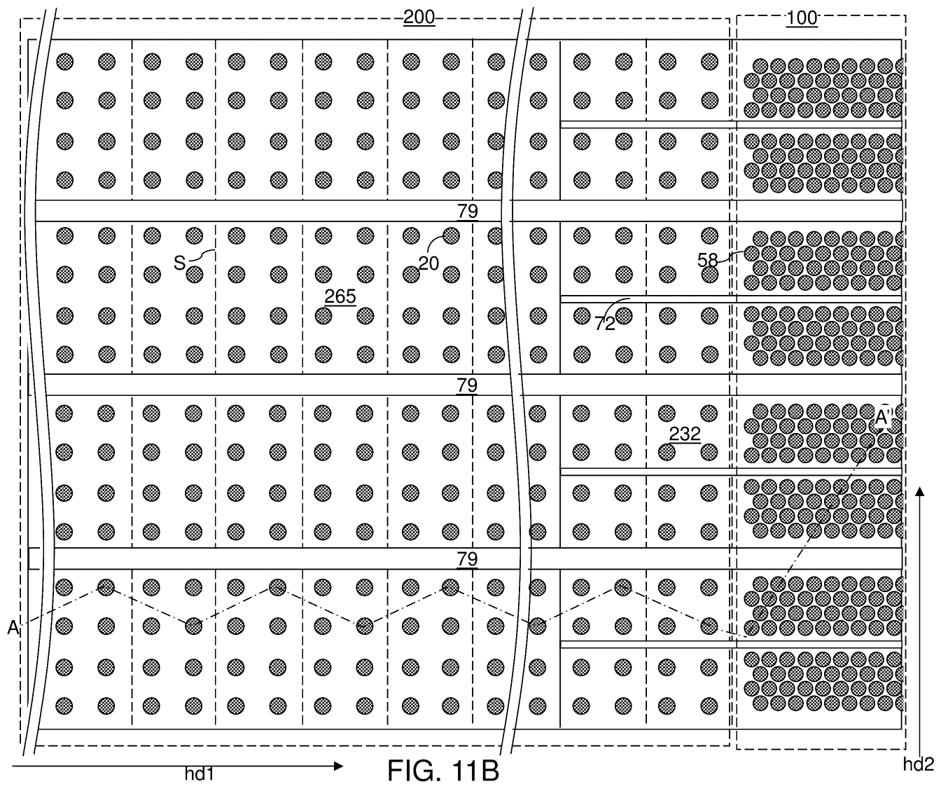

Referring to FIGS. 11A and 11B, a first contact-level dielectric layer 280 may be formed over the second-tier structure (232, 242, 270, 265, 72). The first contact-level dielectric layer 280 includes a dielectric material such as silicon oxide, and may be formed by a conformal or non-conformal deposition process. For example, the first contact-level dielectric layer 280 may include undoped silicate glass and may have a thickness in a range from 100 nm to 600 nm, although lesser and greater thicknesses may also be used.

A photoresist layer may be applied over the first contact-level dielectric layer 280 and may be lithographically patterned to form elongated openings that extend along the first horizontal direction hd1 between clusters of memory opening fill structures 58. Backside trenches 79 may be formed by transferring the pattern in the photoresist layer (not shown) through the first contact-level dielectric layer 280, the second-tier structure (232, 242, 270, 265, 72), and the first-tier structure (132, 142, 170, 165), and into the in-process source-level material layers 110′. Portions of the first contact-level dielectric layer 280, the second-tier structure (232, 242, 270, 265, 72), the first-tier structure (132, 142, 170, 165), and the in-process source-level material layers 110′ that underlie the openings in the photoresist layer may be removed to form the backside trenches 79. In one embodiment, the backside trenches 79 may be formed between clusters of memory stack structures 55. The clusters of the memory stack structures 55 may be laterally spaced apart along the second horizontal direction hd2 by the backside trenches 79.

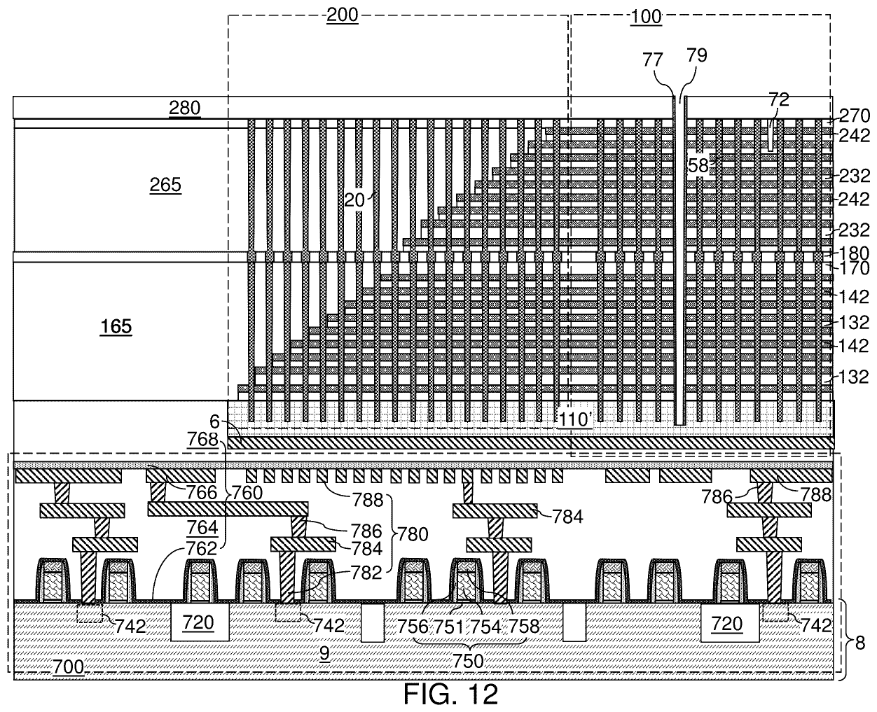

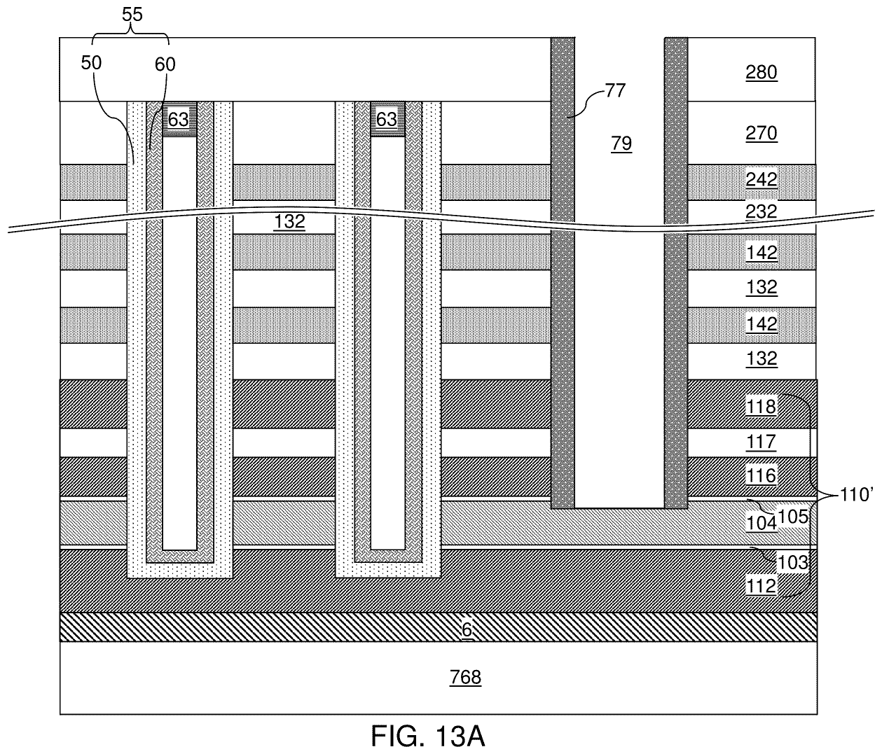

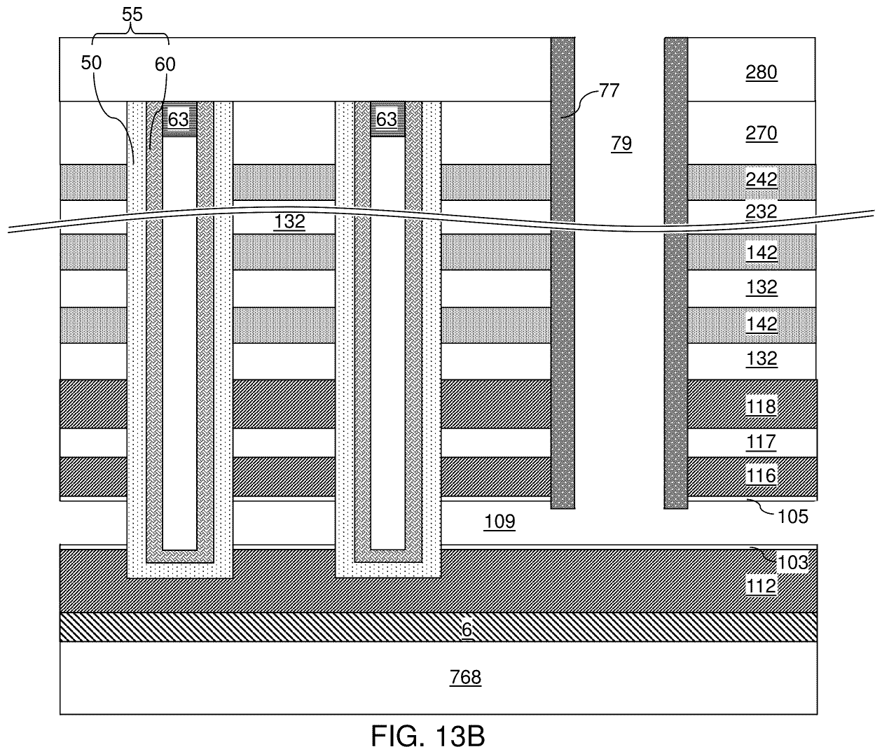

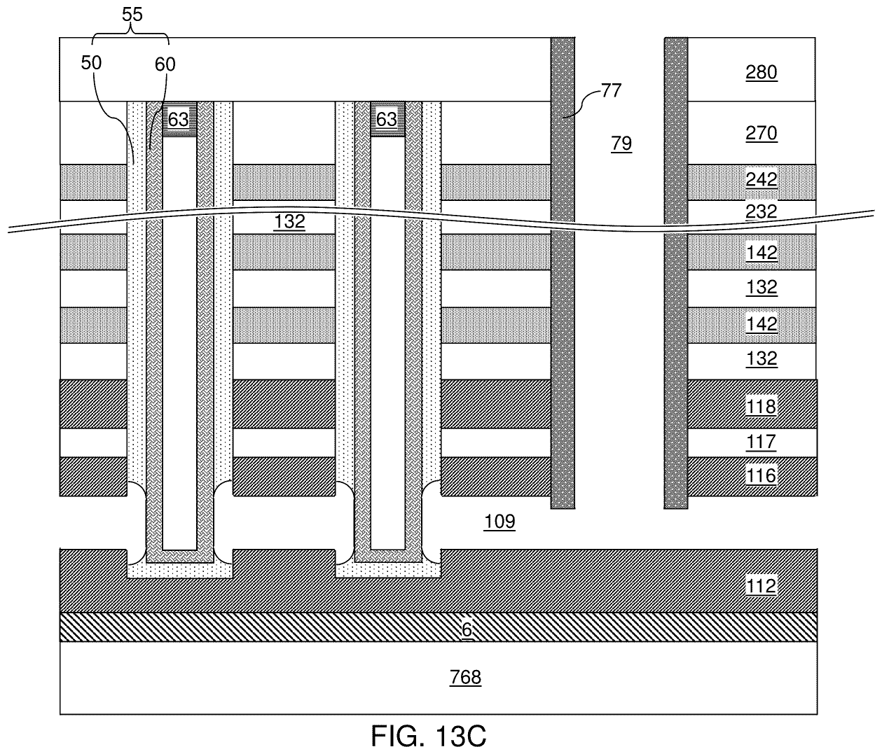

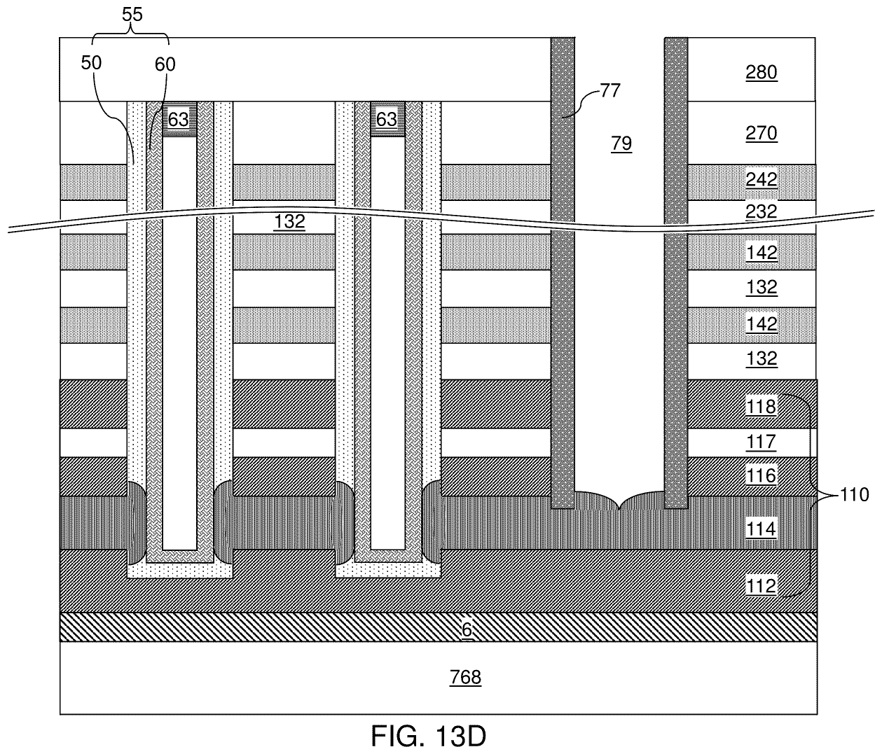

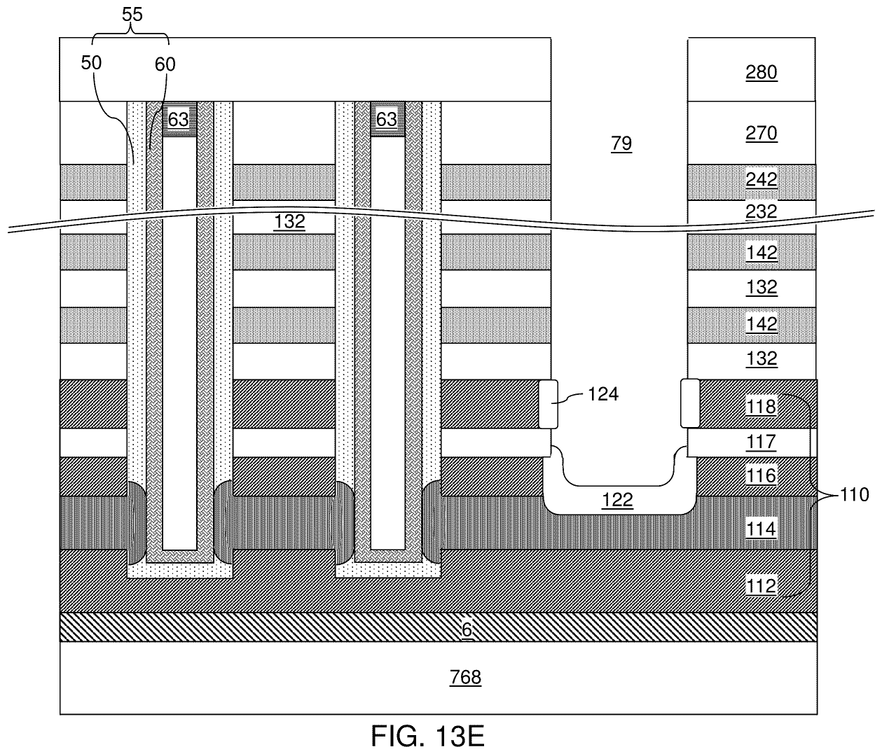

Referring to FIGS. 12 and 13A, a backside trench spacer 77 may be formed on sidewalls of each backside trench 79. For example, a conformal spacer material layer may be deposited in the backside trenches 79 and over the first contact-level dielectric layer 280, and may be anisotropically etched to form the backside trench spacers 77. The backside trench spacers 77 include a material that is different from the material of the source-level sacrificial layer 104. For example, the backside trench spacers 77 may include silicon nitride.

Referring to FIG. 13B, an etchant that etches the material of the source-level sacrificial layer 104 selective to the materials of the first-tier alternating stack (132, 142), the second-tier alternating stack (232, 242), the first and second insulating cap layers (170, 270), the first contact-level dielectric layer 280, the upper sacrificial liner 105, and the lower sacrificial liner 103 may be introduced into the backside trenches in an isotropic etch process. For example, if the source-level sacrificial layer 104 includes undoped amorphous silicon or an undoped amorphous silicon-germanium alloy, the backside trench spacers 77 include silicon nitride, and the upper and lower sacrificial liners (105, 103) include silicon oxide, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the backside trench spacers 77 and the upper and lower sacrificial liners (105, 103). A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the backside trenches 79. Specifically, even if sidewalls of the upper source-level semiconductor layer 116 are physically exposed or even if a surface of the lower source-level semiconductor layer 112 is physically exposed upon formation of the source cavity 109 and/or the backside trench spacers 77, collateral etching of the upper source-level semiconductor layer 116 and/or the lower source-level semiconductor layer 112 is minimal, and the structural change to the exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

Referring to FIG. 13C, a sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper and lower sacrificial liners (105, 103) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners (105, 103). A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

Referring to FIG. 13D, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114, and the source contact layer 114 contacts bottom end portions of inner sidewalls of the backside trench spacers 77. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114.

The layer stack including the lower source-level semiconductor layer 112, the source contact layer 114, and the upper source-level semiconductor layer 116 constitutes a buried source layer (112, 114, 116). The set of layers including the buried source layer (112, 114, 116), the source-level insulating layer 117, and the source-select-level conductive layer 118 constitutes source-level material layers 110, which replaces the in-process source-level material layers 110′.

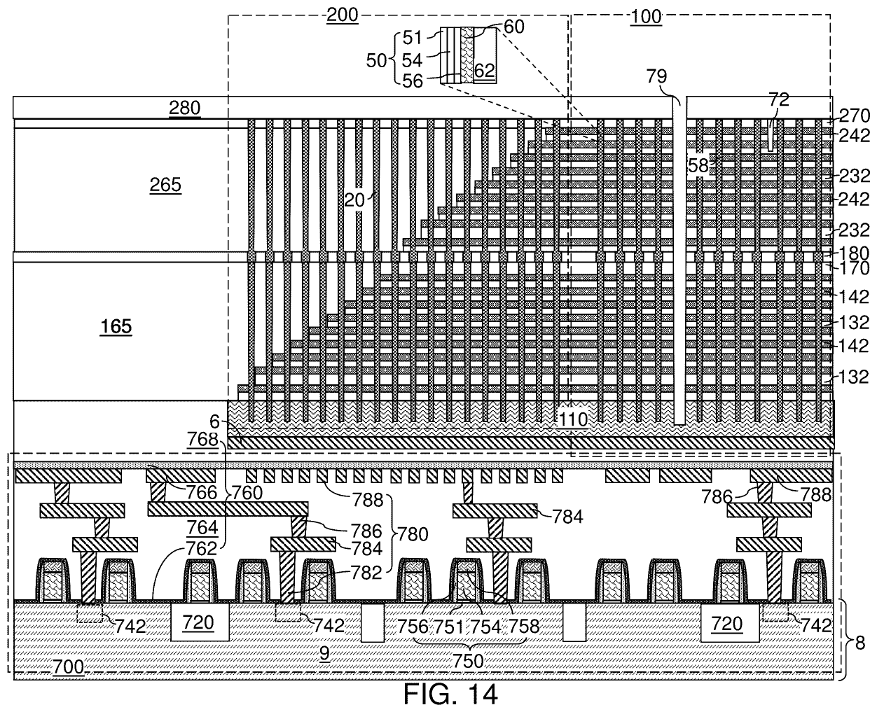

Referring to FIGS. 13E and 14, the backside trench spacers 77 may be removed selective to the insulating layers (132, 232), the first and second insulating cap layers (170, 270), the first contact-level dielectric layer 280, and the source contact layer 114 using an isotropic etch process. For example, if the backside trench spacers 77 include silicon nitride, a wet etch process using hot phosphoric acid may be performed to remove the backside trench spacers 77. In one embodiment, the isotropic etch process that removes the backside trench spacers 77 may be combined with a subsequent isotropic etch process that etches the sacrificial material layers (142, 242) selective to the insulating layers (132, 232), the first and second insulating cap layers (170, 270), the first contact-level dielectric layer 280, and the source contact layer 114.

An oxidation process may be performed to convert physically exposed surface portions of semiconductor materials into dielectric semiconductor oxide portions. For example, surfaces portions of the source contact layer 114 and the upper source-level semiconductor layer 116 may be converted into dielectric semiconductor oxide plates 122, and surface portions of the source-select-level conductive layer 118 may be converted into annular dielectric semiconductor oxide spacers 124.

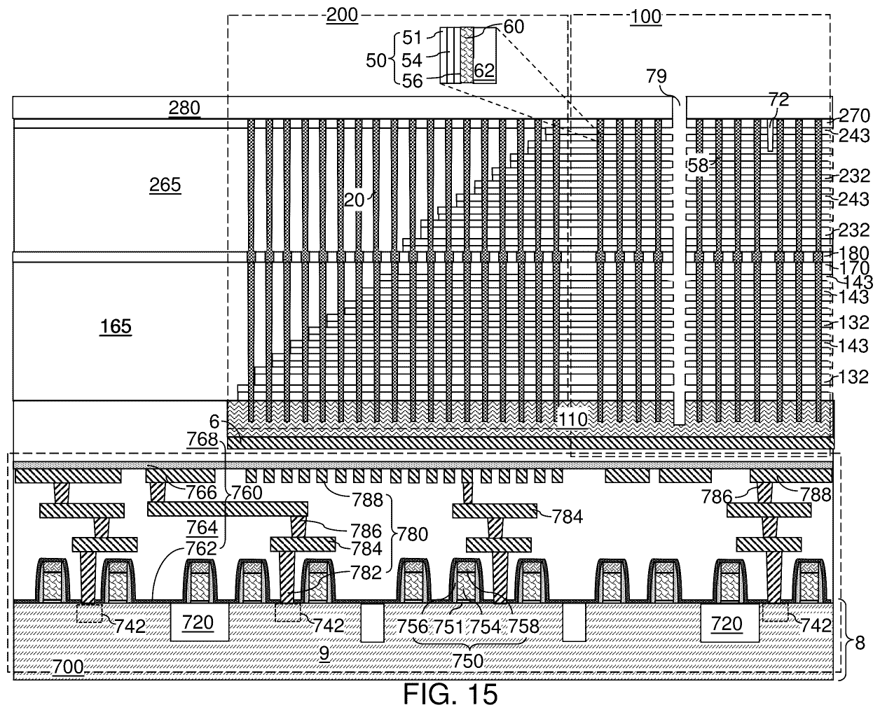

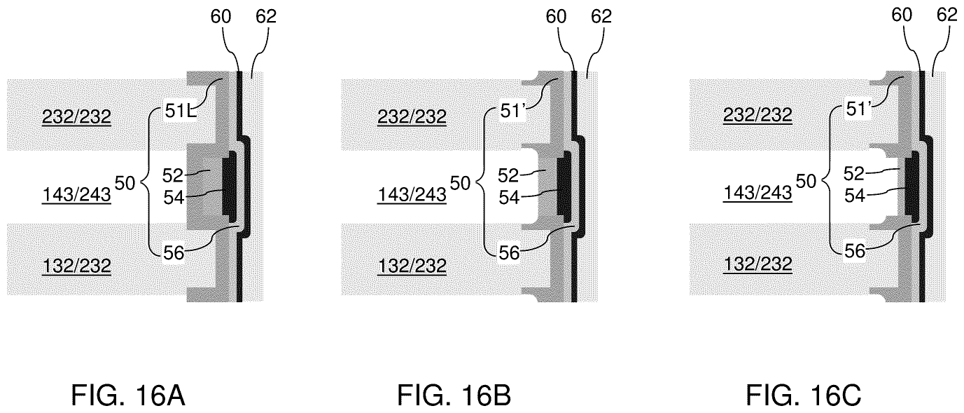

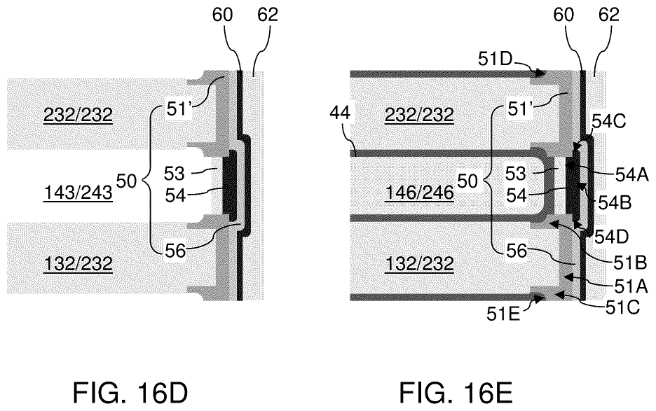

Referring to FIGS. 15 and 16A, the sacrificial material layers (142, 242) are removed selective to the insulating layers (132, 232), the first and second insulating cap layers (170, 270), the first contact-level dielectric layer 280, the dielectric cover layers 51L in the memory opening fill structures 58 and the support pillar structures 20, the source contact layer 114, the dielectric semiconductor oxide plates 122, and the annular dielectric semiconductor oxide spacers 124. FIGS. 16A-16E are sequential vertical cross-sectional views of a first configuration of the first exemplary structure around a backside recess 43 during modification of a memory opening fill structure 58 and formation of electrically conductive layers (146, 246) according to the first embodiment of the present disclosure.

For example, an etchant that selectively etches the materials of the sacrificial material layers (142, 242) with respect to the materials of the insulating layers (132, 232), the first and second insulating cap layers (170, 270), the retro-stepped dielectric material portions (165, 265), and the dielectric cover layers 51L may be introduced into the backside trenches 79, for example, using an isotropic etch process. In one embodiment, the sacrificial material layers (142, 242) may include silicon nitride, the materials of the insulating layers (132, 232), the first and second insulating cap layers (170, 270), the retro-stepped dielectric material portions (165, 265), and the dielectric cover layers 51L may include silicon oxide materials.

The isotropic etch process may be a wet etch process using a wet etch solution, or may be a gas phase (dry) etch process in which the etchant is introduced in a vapor phase into the backside trench 79. For example, if the sacrificial material layers (142, 242) include silicon nitride, the etch process may be a wet etch process in which the exemplary structure is immersed within a wet etch tank including phosphoric acid, which etches silicon nitride selective to silicon oxide, silicon, and various other materials used in the art.

Backside recesses (143, 243) are formed in volumes from which the sacrificial material layers (142, 242) are removed. The backside recesses (143, 243) include first backside recesses 143 that are formed in volumes from which the first sacrificial material layers 142 are removed and second backside recesses 243 that are formed in volumes from which the second sacrificial material layers 242 are removed. Each of the backside recesses (143, 243) may be a laterally extending cavity having a lateral dimension that is greater than the vertical extent of the cavity. In other words, the lateral dimension of each of the backside recesses (143, 243) may be greater than the height of the respective backside recess (143, 243). A plurality of backside recesses (143, 243) may be formed in the volumes from which the material of the sacrificial material layers (142, 242) is removed. Each of the backside recesses (143, 243) may extend substantially parallel to the top surface of the substrate semiconductor layer 9. A backside recess (143, 243) may be vertically bounded by a top surface of an underlying insulating layer (132, 232) and a bottom surface of an overlying insulating layer (132, 232). In one embodiment, each of the backside recesses (143, 243) may have a uniform height throughout. The outer cylindrical surface segments of the dielectric cover layer 51L may be physically exposed to the backside recesses (143, 243).

Referring to FIG. 16B, portions of the dielectric cover layer 51L that are exposed in the backside recesses (143, 243) can be removed by performing an isotropic etch process. The isotropic etch process etches the material of the dielectric cover layer 51L, and may collaterally recess surface portions of the insulating layers (132, 232), the insulating cap layers (170, 270), the inter-tier dielectric layer 180, and the first contact-level dielectric layer 280. In one embodiment, the dielectric cover layer 51L may comprise a silicon oxide based material, and the isotropic etch process may comprise a wet etch process employing dilute hydrofluoric acid. The duration of the isotropic etch process can be selected such that portions of the dielectric cover layer 51L located at the levels of the backside recesses (143, 243) are removed, and outer cylindrical sidewalls of the discrete seed material portions 52 are physically exposed.

Each remaining portion of the dielectric cover layer 51L located on a respective one of the insulating layers (132, 232) constitutes a dielectric cover material portion 51′. A vertical stack of dielectric cover material portions 51′ can be formed within each memory opening 49. Each dielectric cover material portion 51′ within the vertical stack of dielectric cover material portions 51′ contacts a cylindrical sidewall of a respective one of the insulating layers (132, 232). Outer cylindrical sidewalls of the discrete seed material portions 52 are physically exposed to the backside recesses (143, 243).

Referring to FIG. 16C, the discrete seed material portions 52 may be optionally thinned. In case the discrete seed material portions 52 comprise silicon, a timed wet etch process employing hot trimethyl-2 hydroxyethyl ammonium hydroxide (“hot TMY”) or tetramethyl ammonium hydroxide (TMAH) may be performed to thin the discrete seed material portions 52. In case the discrete seed material portions 52 comprise silicon nitride, a time wet etch process employing phosphoric acid may be employed. The etch distance of the timed isotropic etch process may be in a range from 1% to 80%, such as from 5% to 50%, of the thickness of the discrete seed material portions 52 (as measured between an outer cylindrical sidewall and an inner cylindrical sidewall).

Referring to FIG. 16D, an oxidation process may be performed to convert the vertical stack of discrete seed material portions 52 into a vertical stack of discrete blocking dielectric material portions 53. In case the discrete seed material portions 52 comprise silicon, the discrete blocking dielectric material portions 53 may consist essentially of silicon oxide with a homogeneous material composition throughout. In case the discrete seed material portions 52 comprise silicon nitride, the discrete blocking dielectric material portions 53 may comprise a silicon oxide material which optionally includes residual nitrogen atoms at an interface with a respective one of the contoured charge storage material portions 54. In one embodiment, each of the discrete blocking dielectric material portions 53 may comprise nitrogen atoms at a variable atomic concentration that decreases with a lateral distance from a cylindrical interface with a respective one of the contoured charge storage material portions 54. Generally, the discrete blocking dielectric material portions 53 are vertically spaced apart from each other, and are interlaced with the vertical stack of dielectric cover material portions 51′ along a vertical direction. In one embodiment, the discrete blocking dielectric material portions 53 may have a uniform lateral thickness between an outer cylindrical sidewall and an inner cylindrical sidewall.

Referring to FIG. 16E, a backside blocking dielectric layer 44 may be optionally deposited in the backside recesses (143, 243) and the backside trenches 79 and over the first contact-level dielectric layer 280. The backside blocking dielectric layer 44 includes a dielectric metal oxide material, which may comprise aluminum oxide or a dielectric oxide of a transition metal. For example, the backside blocking dielectric layer 44 may include aluminum oxide. The backside blocking dielectric layer 44 may be formed by a conformal deposition process such as atomic layer deposition or chemical vapor deposition. The thickness of the backside blocking dielectric layer 44 may be in a range from 1 nm to 20 nm, such as from 2 nm to 10 nm, although lesser and greater thicknesses may also be used. In one embodiment, each dielectric cover material portion 51′ may comprise an upper annular concave surface segment that contacts a convex surface segment of a respective first portion of the backside blocking dielectric layer 44, and a lower annular concave surface segment that contacts a convex surface segment of a respective second portion of the backside blocking dielectric layer 44.

At least one conductive material may be deposited over the blocking dielectric layer 44 in the plurality of backside recesses (143, 243), on the sidewalls of the backside trenches 79, and over the first contact-level dielectric layer 280. The at least one conductive material may be deposited by a conformal deposition method, which may be, for example, chemical vapor deposition (CVD), atomic layer deposition (ALD), electroless plating, electroplating, or a combination thereof. The at least one conductive material may include an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof.

In one embodiment, the at least one conductive material may include at least one metallic material, i.e., an electrically conductive material that includes at least one metallic element. Non-limiting exemplary metallic materials that may be deposited in the backside recesses (143, 243) include tungsten, tungsten nitride, titanium, titanium nitride, tantalum, tantalum nitride, cobalt, and ruthenium. For example, the at least one conductive material may include a conductive metallic nitride liner that includes a conductive metallic nitride material such as TiN, TaN, WN, or a combination thereof, and a conductive fill material such as W, Co, Ru, Mo, Cu, or combinations thereof. In one embodiment, the at least one conductive material for filling the backside recesses (143, 243) may be a combination of titanium nitride layer and a tungsten fill material.

Electrically conductive layers (146, 246) may be formed in the backside recesses (143, 243) by deposition of the at least one conductive material. A plurality of first electrically conductive layers 146 may be formed in the plurality of first backside recesses 143, a plurality of second electrically conductive layers 246 may be formed in the plurality of second backside recesses 243, and a continuous metallic material layer (not shown) may be formed on the sidewalls of each backside trench 79 and over the first contact-level dielectric layer 280. Each of the first electrically conductive layers 146 and the second electrically conductive layers 246 may include a respective conductive metallic nitride liner and a respective conductive fill material. Thus, the first and second sacrificial material layers (142, 242) may be replaced with the first and second electrically conductive layers (146, 246), respectively. Specifically, each first sacrificial material layer 142 may be replaced with an optional portion of the backside blocking dielectric layer and a first electrically conductive layer 146, and each second sacrificial material layer 242 may be replaced with an optional portion of the backside blocking dielectric layer and a second electrically conductive layer 246. A backside cavity is present in the portion of each backside trench 79 that is not filled with the continuous metallic material layer.

Residual conductive material may be removed from inside the backside trenches 79. Specifically, the deposited metallic material of the continuous metallic material layer may be etched back from the sidewalls of each backside trench 79 and from above the first contact-level dielectric layer 280, for example, by an anisotropic or isotropic etch. Each remaining portion of the deposited metallic material in the first backside recesses constitutes a first electrically conductive layer 146. Each remaining portion of the deposited metallic material in the second backside recesses constitutes a second electrically conductive layer 246. Sidewalls of the first electrically conductive material layers 146 and the second electrically conductive layers may be physically exposed to a respective backside trench 79. The backside trenches may have a pair of curved sidewalls having a non-periodic width variation along the first horizontal direction hd1 and a non-linear width variation along the vertical direction.

Each electrically conductive layer (146, 246) may be a conductive sheet including openings therein. A first subset of the openings through each electrically conductive layer (146, 246) may be filled with memory opening fill structures 58. A second subset of the openings through each electrically conductive layer (146, 246) may be filled with the support pillar structures 20. Each electrically conductive layer (146, 246) may have a lesser area than any underlying electrically conductive layer (146, 246) because of the first and second stepped surfaces. Each electrically conductive layer (146, 246) may have a greater area than any overlying electrically conductive layer (146, 246) because of the first and second stepped surfaces.

In some embodiment, drain-select-level isolation structures 72 may be provided at topmost levels of the second electrically conductive layers 246. A subset of the second electrically conductive layers 246 located at the levels of the drain-select-level isolation structures 72 constitutes drain select gate electrodes. A subset of the electrically conductive layer (146, 246) located underneath the drain select gate electrodes may function as combinations of a control gate and a word line located at the same level. The control gate electrodes within each electrically conductive layer (146, 246) are the control gate electrodes for a vertical memory device including the memory stack structure 55.

Each of the memory stack structures 55 comprises a vertical stack of memory elements located at each level of the electrically conductive layers (146, 246). A subset of the electrically conductive layers (146, 246) may comprise word lines for the memory elements. The semiconductor devices in the underlying peripheral device region 700 may comprise word line switch devices configured to control a bias voltage to respective word lines. The memory-level assembly is located over the substrate semiconductor layer 9. The memory-level assembly includes at least one alternating stack (132, 146, 232, 246) and memory stack structures 55 vertically extending through the at least one alternating stack (132, 146, 232, 246).

A memory opening fill structure 58 can be formed in each memory opening 49. The memory opening fill structure 58 comprises a vertical stack of blocking dielectric material portions 53 located at the levels of the electrically conductive layers (146, 246), a vertical stack of discrete memory elements located at the levels of the electrically conductive layers (146, 246) and comprising a respective contoured charge storage material portion 54 having a straight outer cylindrical sidewall 54A and a contoured inner sidewall having an inner cylindrical sidewall segment 54B, an upper annular convex sidewall segment 54C, and a lower annular convex sidewall segment 54D, a tunneling dielectric layer 56 overlying the contoured inner sidewalls of the contoured charge storage material portion 54, and a vertical semiconductor channel 60.

In one embodiment, the contoured charge storage material portions 54 comprise a material selected from ruthenium, tungsten, silicon nitride, or silicon. In one embodiment, the blocking dielectric material portions 53 comprise a silicon oxide material. In one embodiment, the blocking dielectric material portions 53 are discrete blocking dielectric material portions 53 that are vertically spaced apart from each other and interlaced with a vertical stack of dielectric cover material portions 51′ along a vertical direction; and the dielectric cover material portions 51′ comprise a material selected from silicon oxynitride, carbon-doped silicon oxynitride, or silicon oxide.

In one embodiment, each of the dielectric cover material portions 51′ contacts a cylindrical sidewall, an annular top surface segment, and an annular bottom surface segment of a respective insulating layer (132, 232) of the insulating layers (132, 232) of the alternating stack {(132, 146), (232, 246)}. In one embodiment, each of the dielectric cover material portions 51′ comprises a vertical portion 51A connected to upper and lower horizontal portions (51B, 51C). The upper horizontal portion 51B includes an upper annular concave surface segment 51D, and the lower horizontal portion 51C includes a lower annular concave surface segment 51E.

In one embodiment, each of the blocking dielectric material portions 53 comprise a respective inner cylindrical sidewall that contacts a straight outer cylindrical sidewall 54A of a respective contoured charge storage material portion 54, a respective outer cylindrical sidewall, a respective upper annular top surface, and a respective lower annular top surface. In one embodiment, each of the blocking dielectric material portions 53 comprises nitrogen atoms at a variable atomic concentration that decreases with a lateral distance from a cylindrical interface with a respective one of the contoured charge storage material portions 54.

In one embodiment, each of the electrically conductive layers (146, 246) is spaced from a respective neighboring pair of insulating layers (132, 232) of the insulating layers (132, 232) of the alternating stack {(132, 146), (232, 246)} and from the memory opening fill structure 58 by a respective backside blocking dielectric layer 44 comprising a dielectric metal oxide material.

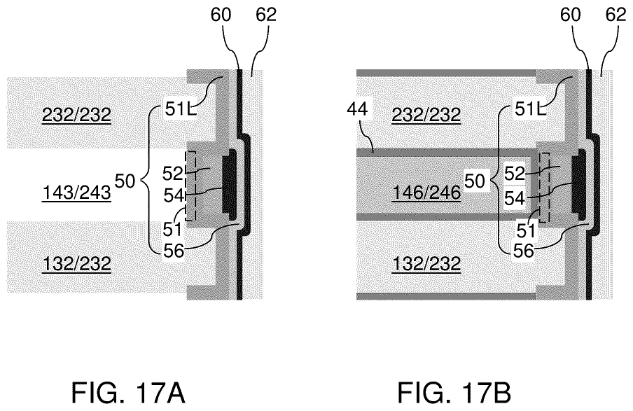

FIGS. 17A and 17B are sequential vertical cross-sectional views of a second configuration of the exemplary structure around a backside recess (143, 243) during modification of a memory opening fill structure 58 and formation of electrically conductive layers (146, 246) according to the second embodiment of the present disclosure.

Referring to FIG. 17A, the second configuration of the exemplary structure is illustrated at the processing steps of FIGS. 16 and 17A. The second configuration of the exemplary structure illustrated in FIG. 17A can be the same as the first configuration of the exemplary structure illustrated in FIG. 16A.

In the second configuration of the exemplary structure, the tubular dielectric material portions of the dielectric cover layer 51L function as blocking dielectric material portions. In this configuration, the tubular dielectric material portions are referred to as blocking dielectric material portions 51. A vertical stack of blocking dielectric material portions 51 may be present within each dielectric cover layer 51L at the levels of the backside recesses (143, 243), which are the same as the levels of the sacrificial material layers (142, 242) and the levels of the electrically conductive layers to be subsequently formed (146, 246). Further, the discrete seed material portions 52 (which have a respective tubular configuration) are employed as an additional components of the memory elements for storing electrical charges. As such, the discrete seed material portions 52 in the second configuration of the exemplary structure are herein referred to as tubular charge storage material portions 52.

Referring to FIG. 17B, the processing steps described with reference to FIG. 16E can be performed to form a combination of a backside blocking dielectric layer 44 and an electrically conductive layer (146, 246) within each backside recess (143, 243). Each outer cylindrical sidewall of the blocking dielectric material portions 51 may be contacted by a cylindrical surface segment of a respective backside blocking dielectric layer 44 that extends from a top surface of an underlying insulating layer (132, 232) to a bottom surface of an overlying insulating layer (132, 232).

A memory opening fill structure 58 can be formed in each memory opening 49. The memory opening fill structure 58 comprises a vertical stack of blocking dielectric material portions 51 located at the levels of the electrically conductive layers (146, 246), a vertical stack of discrete memory elements (comprising combinations of a contoured charge storage material portion 54 and a tubular charge storage material portion 52) located at the levels of the electrically conductive layers (146, 246) and comprising a respective contoured charge storage material portion 54 having a straight outer cylindrical sidewall and a contoured inner sidewall having an inner cylindrical sidewall segment, an upper annular convex sidewall segment, and a lower annular convex sidewall segment, a tunneling dielectric layer 56 overlying the contoured inner sidewalls of the contoured charge storage material portion 54, and a vertical semiconductor channel 60.

In one embodiment, the contoured charge storage material portions 54 comprise a material selected from ruthenium, tungsten, silicon nitride, or silicon, while tubular charge storage material portions 52 comprise silicon or silicon nitride. The contoured charge storage material portions 54 and the tubular charge storage material portions 52 may comprise the same material or different materials from each other. In one embodiment, the blocking dielectric material portions 51 comprise a silicon oxide material.

In one embodiment, each of the discrete memory elements (52, 54) comprises a respective tubular charge storage material portion 52 having a straight inner sidewall contacting a straight outer cylindrical sidewall of a respective contoured charge storage material portion 54.

In one embodiment, the blocking dielectric material portions 51 are portions of a dielectric cover layer 51L that are located at the levels of the electrically conductive layers (146, 246), wherein the dielectric cover layer 51L vertically extends continuously through each electrically conductive layer (146, 246) and each insulating layer (132, 232) within the alternating stack {(132, 146), (232, 246)}.

In one embodiment, each of the electrically conductive layers (146, 246) is spaced from a respective neighboring pair of insulating layers (132, 232) among the insulating layers (132, 232) of the alternating stack {(132, 146), (232, 246)} and from the memory opening fill structure 58 by a respective backside blocking dielectric layer 44 comprising a dielectric metal oxide material.

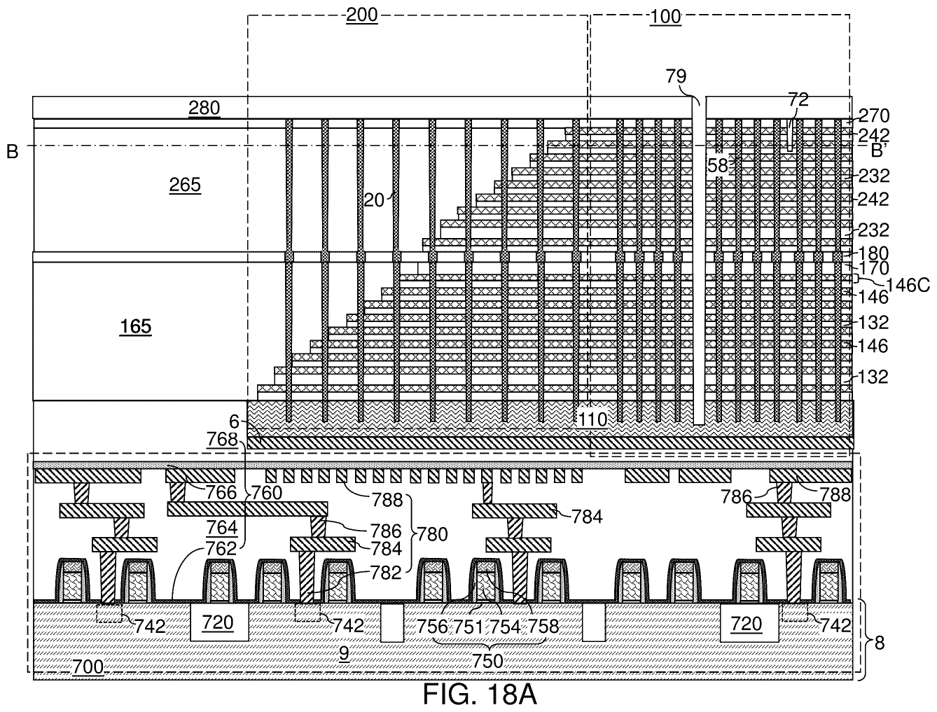

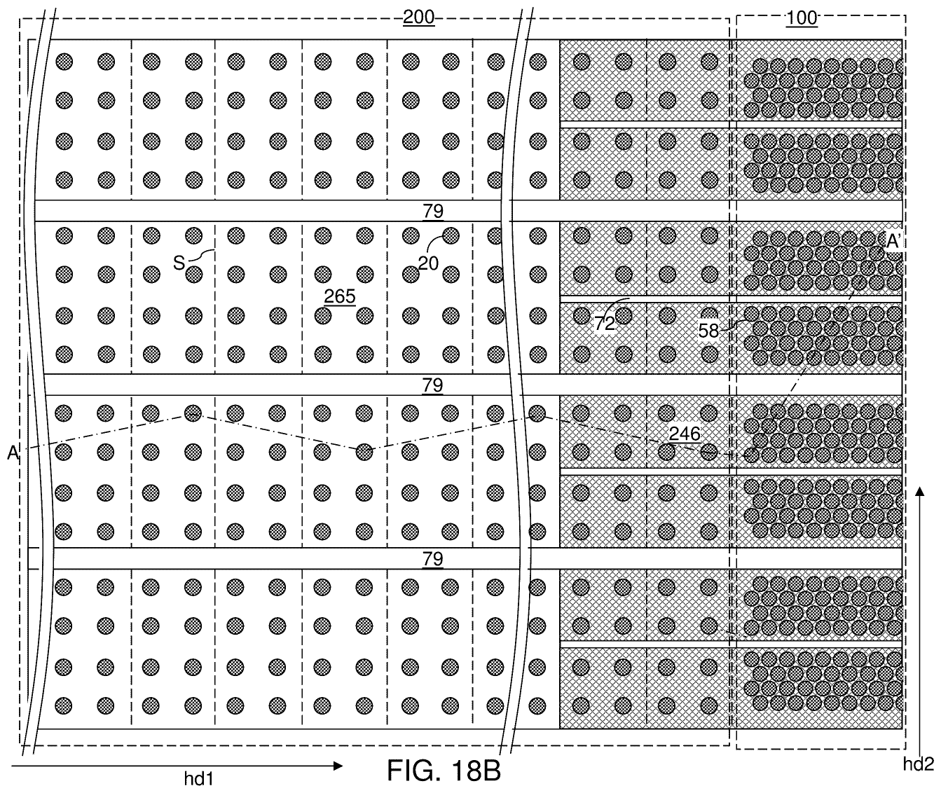

Referring to FIGS. 18A and 18B, the exemplary structure is illustrated after formation of the electrically conductive layers (146, 246), i.e., after the processing steps described with reference to FIG. 16E or after the processing steps described with reference to FIG. 17B.

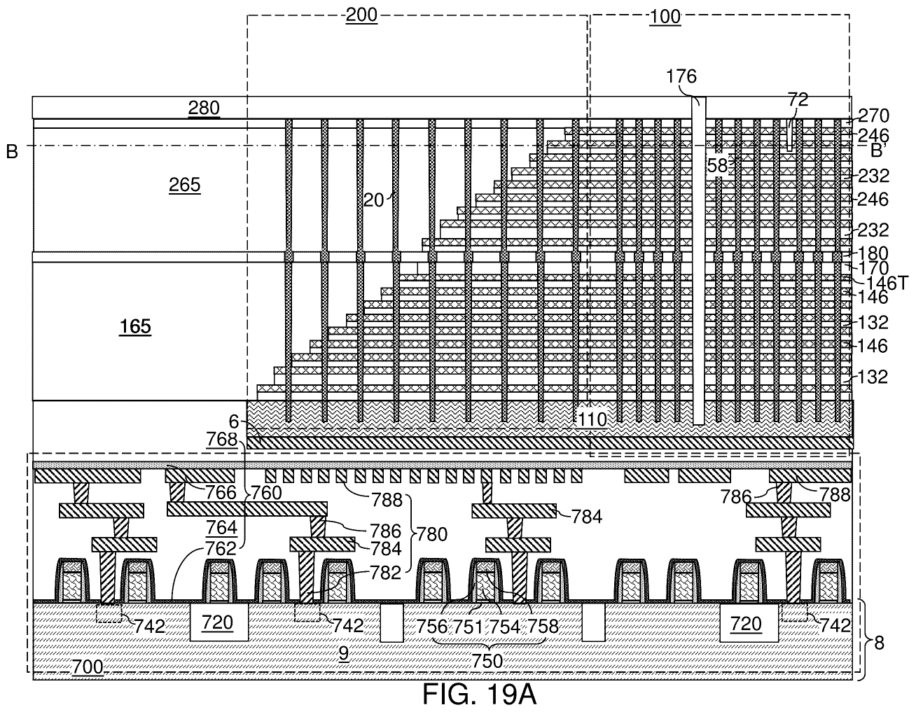

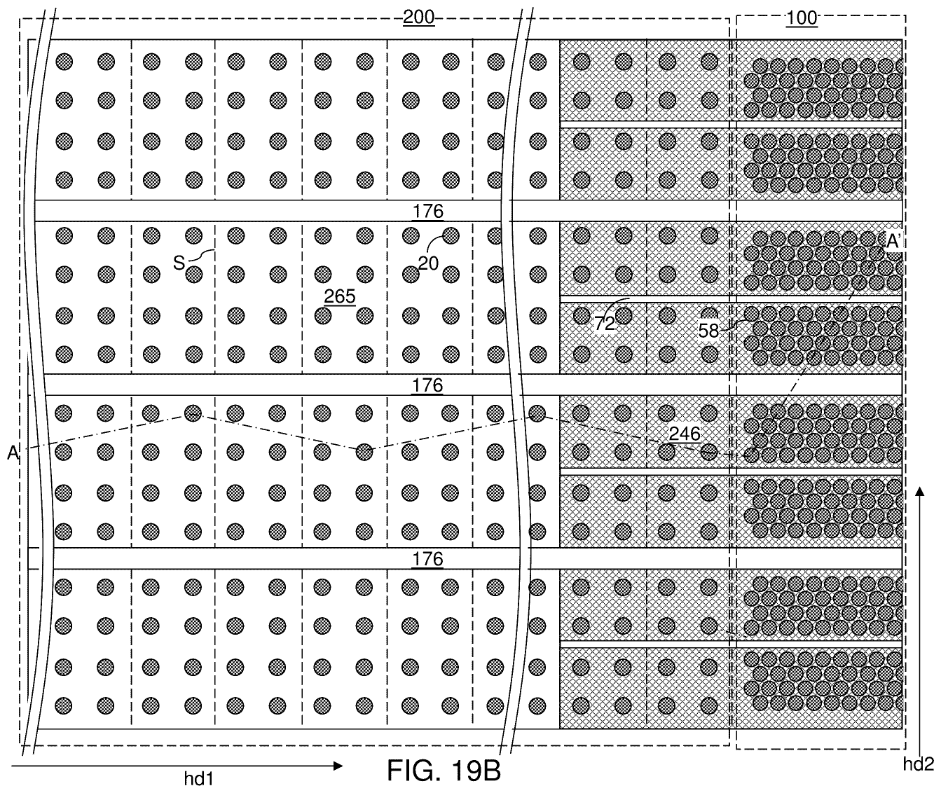

Referring to FIGS. 19A and 19B, a dielectric material layer may be conformally deposited in the backside trenches 79 and over the first contact-level dielectric layer 280 by a conformal deposition process. The dielectric material layer may include, for example, silicon oxide.

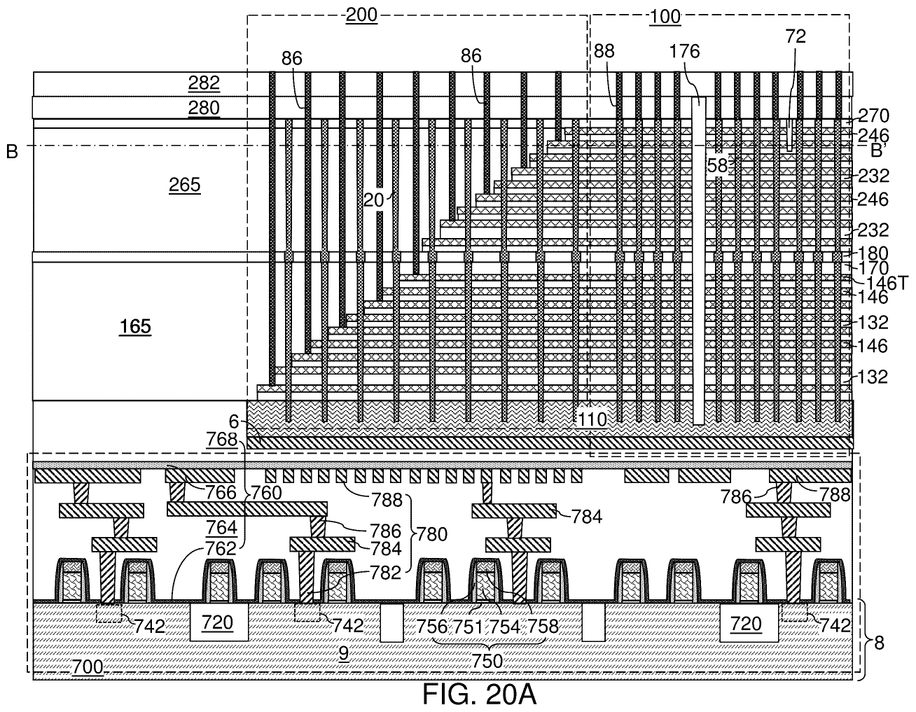

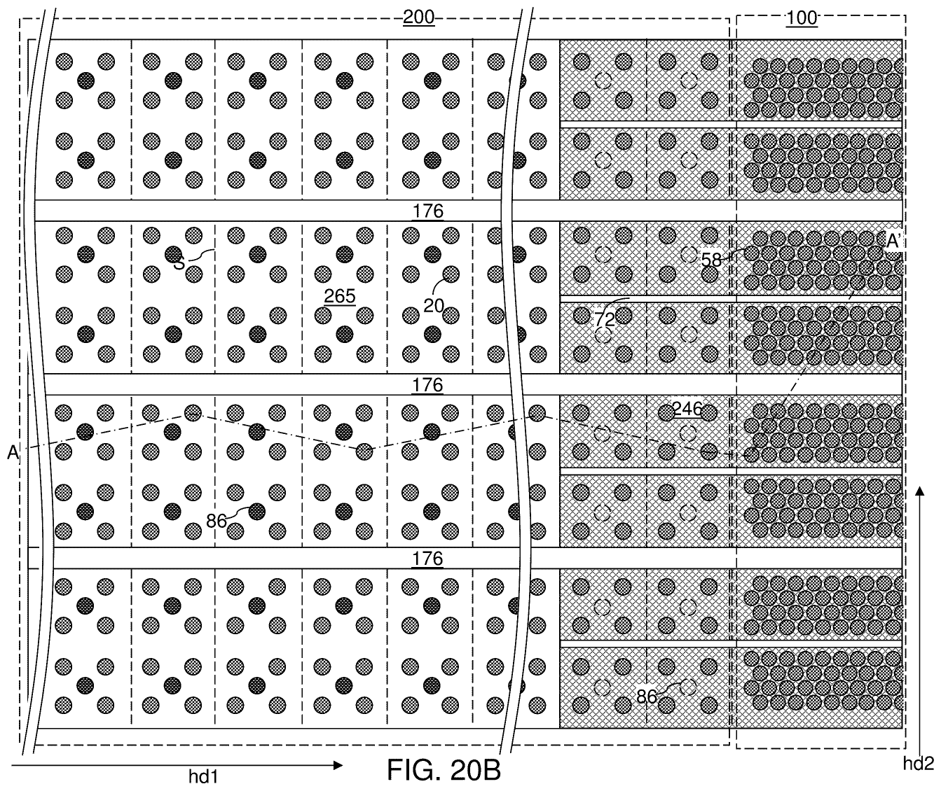

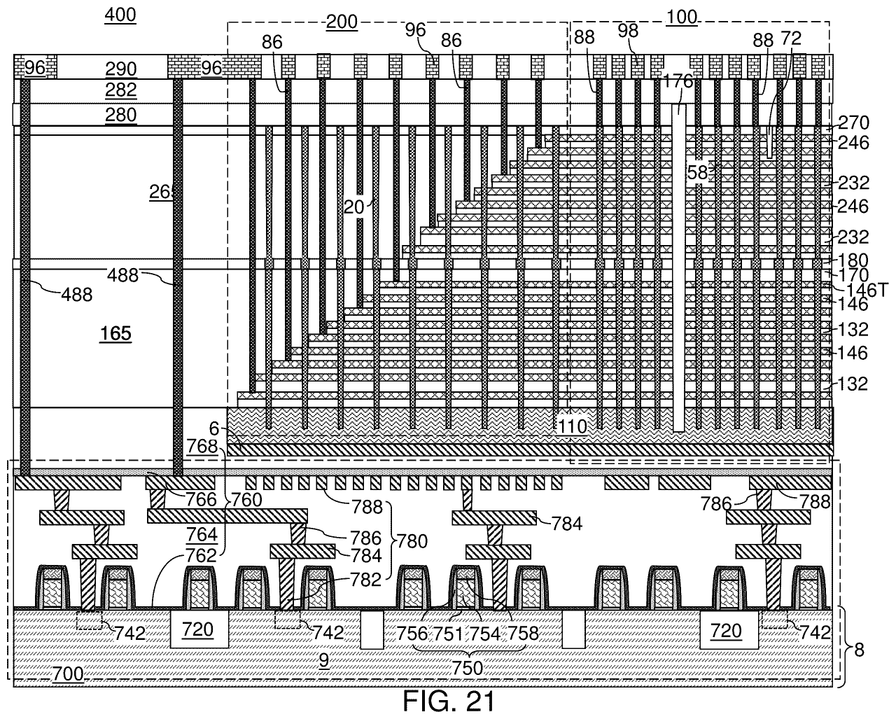

Referring to FIGS. 20A and 20B, a second contact-level dielectric layer 282 may be formed over the first contact-level dielectric layer 280. The second contact-level dielectric layer 282 includes a dielectric material such as silicon oxide, and may have a thickness in a range from 100 nm to 600 nm, although lesser and greater thicknesses may also be used.

A photoresist layer (not shown) may be applied over the second contact-level dielectric layer 282, and may be lithographically patterned to form various contact via openings. For example, openings for forming drain contact via structures may be formed in the memory array region 100, and openings for forming staircase region contact via structures may be formed in the staircase region 200. An anisotropic etch process is performed to transfer the pattern in the photoresist layer through the second and first contact-level dielectric layers (282, 280) and underlying dielectric material portions. The drain regions 63 and the electrically conductive layers (146, 246) may be used as etch stop structures. Drain contact via cavities may be formed over each drain region 63, and staircase-region contact via cavities may be formed over each electrically conductive layer (146. 246) at the stepped surfaces underlying the first and second retro-stepped dielectric material portions (165, 265). The photoresist layer may be subsequently removed, for example, by ashing.

Drain contact via structures 88 are formed in the drain contact via cavities and on a top surface of a respective one of the drain regions 63. Staircase-region contact via structures 86 are formed in the staircase-region contact via cavities and on a top surface of a respective one of the electrically conductive layers (146, 246). The staircase-region contact via structures 86 may include drain select level contact via structures that contact a subset of the second electrically conductive layers 246 that function as drain select level gate electrodes. Further, the staircase-region contact via structures 86 may include word line contact via structures that contact electrically conductive layers (146, 246) that underlie the drain select level gate electrodes and function as word lines for the memory stack structures 55.

Referring to FIG. 21, peripheral-region via cavities may be formed through the second and first contact-level dielectric layers (282, 280), the second and first retro-stepped dielectric material portions (265, 165), and the at least one second dielectric layer 768 to top surfaces of a first subset of the lower-level metal interconnect structure 780 in the peripheral device region 400. At least one conductive material may be deposited in the peripheral-region via cavities. Excess portions of the at least one conductive material may be removed from above the horizontal plane including the top surface of the second contact-level dielectric layer 282. Each remaining portion of the at least one conductive material in a peripheral-region via cavity constitutes a peripheral-region contact via structure 488.

At least one additional dielectric layer may be formed over the contact-level dielectric layers (280, 282), and additional metal interconnect structures (herein referred to as upper-level metal interconnect structures) may be formed in the at least one additional dielectric layer. For example, the at least one additional dielectric layer may include a line-level dielectric layer 290 that is formed over the contact-level dielectric layers (280, 282). The upper-level metal interconnect structures may include bit lines 98 contacting a respective one of the drain contact via structures 88, and interconnection line structures 96 contacting, and/or electrically connected to, at least one of the staircase-region contact via structures 86 and/or the peripheral-region contact via structures 488 and/or the through-memory-region via structures 588. The word line contact via structures (which are provided as a subset of the staircase-region contact via structures 86) may be electrically connected to the word line driver circuit through a subset of the lower-level metal interconnect structures 780 and through a subset of the peripheral-region contact via structures 488.

In one embodiment, the three-dimensional memory device comprises a three-dimensional NAND memory device, the electrically conductive strips (146, 246) comprise, or are electrically connected to, a respective word line of the three-dimensional NAND memory device, the substrate 8 comprises a silicon substrate, the three-dimensional NAND memory device comprises an array of three-dimensional NAND strings over the silicon substrate, and at least one memory cell in a first device level of the array of three-dimensional NAND strings is located over another memory cell in a second device level of the array of three-dimensional NAND strings. The silicon substrate may contain an integrated circuit comprising a driver circuit for the memory device located thereon, the electrically conductive strips (146, 246) comprise a plurality of control gate electrodes having a strip shape extending substantially parallel to the top surface of the substrate 8, the plurality of control gate electrodes comprise at least a first control gate electrode located in the first device level and a second control gate electrode located in the second device level. The array of three-dimensional NAND strings comprises a plurality of semiconductor channels 60, wherein at least one end portion of each of the plurality of semiconductor channels 60 extends substantially perpendicular to a top surface of the substrate 8, and one of the plurality of semiconductor channels including the vertical semiconductor channel 60. The array of three-dimensional NAND strings comprises a plurality of charge storage elements (comprising portions of the memory films 50), each charge storage element located adjacent to a respective one of the plurality of semiconductor channels 60.

Referring to all drawings and according to various embodiments of the present disclosure, a memory device comprises: an alternating stack {(132, 146), (232, 246)} of insulating layers (132, 232) and electrically conductive layers (146, 246); a memory opening 49 vertically extending through the alternating stack {(132, 146), (232, 246)} and having a lateral undulation in a vertical cross-sectional profile such that the memory opening 49 laterally protrudes outward at levels of the electrically conductive layers (146, 246); and a memory opening fill structure 58 located in the memory opening 49 and comprising a vertical stack of blocking dielectric material portions (53 or 51) located at the levels of the electrically conductive layers (146, 246), a vertical stack of discrete memory elements {54 or (52, 54)} located at the levels of the electrically conductive layers (146, 246) and comprising a respective contoured charge storage material portion 54 having a straight outer cylindrical sidewall 54A and a contoured inner sidewall having an inner cylindrical sidewall segment 54B, an upper annular convex sidewall segment 54C, and a lower annular convex sidewall segment 54D, a tunneling dielectric layer 56 overlying the contoured inner sidewalls of the contoured charge storage material portion 54, and a vertical semiconductor channel 60.

In one embodiment shown in FIG. 9F, the contoured charge storage material portion has a “mushroom” shape, and comprises an outer “stem” portion 54X having a first height and an inner “head” portion 54Y having a second height greater than the first height. As used herein, the height is the direction perpendicular to the top surface of the substrate 8.

In one embodiment, the contoured charge storage material portions 54 comprise a material selected from ruthenium, tungsten, silicon nitride, or silicon. In one embodiment, the blocking dielectric material portions (53 or 51) comprise silicon oxide.

In one embodiment, the blocking dielectric material portions 53 are discrete blocking dielectric material portions 53 that are vertically spaced apart from each other and interlaced with a vertical stack of dielectric cover material portions 51′ along a vertical direction; and the dielectric cover material portions 51′ comprise a material selected from silicon oxynitride, carbon-doped silicon oxynitride, or silicon oxide. In one embodiment, each of the dielectric cover material portions 51′ contacts a cylindrical sidewall, an annular top surface segment, and an annular bottom surface segment of a respective insulating layer (132, 232) of the insulating layers (132, 232) of the alternating stack {(132, 146), (232, 246)}.

In one embodiment, each of the dielectric cover material portions 51′ comprises an upper annular concave surface segment and a lower annular concave surface segment. In one embodiment, each of the blocking dielectric material portions 53 comprise a respective inner cylindrical sidewall that contacts a straight outer cylindrical sidewall of a respective contoured charge storage material portion 54, a respective outer cylindrical sidewall, a respective upper annular top surface, and a respective lower annular top surface. In one embodiment, each of the blocking dielectric material portions 53 comprises nitrogen atoms at a variable atomic concentration that decreases with a lateral distance from a cylindrical interface with a respective one of the contoured charge storage material portions 54.

In one embodiment, the blocking dielectric material portions 51 are portions of a dielectric cover layer 51L that are located at the levels of the electrically conductive layers (146, 246), wherein the dielectric cover layer 51L vertically extends continuously through each electrically conductive layer (146, 246) within the alternating stack {(132, 146), (232, 246)}. In one embodiment, each of the discrete memory elements (52, 54) comprises a respective tubular charge storage material portion 52 having a straight inner sidewall contacting a straight outer cylindrical sidewall of a respective contoured charge storage material portion 54. In one embodiment, the tubular charge storage material portions 52 comprise silicon nitride or silicon.

In one embodiment, the tubular charge storage material portions 52 comprise a different material than the contoured charge storage material portions 54.

In one embodiment, each of the electrically conductive layers (146, 246) is spaced from a respective neighboring pair of insulating layers (132, 232) of the insulating layers (132, 232) of the alternating stack {(132, 146), (232, 246)} and from the memory opening fill structure 58 by a respective backside blocking dielectric layer 44 comprising a dielectric metal oxide material.

The various embodiments of the present disclosure may be employed to provide discrete memory elements {54 or (52, 54)} (which may be charge storage elements, such as floating gates and/or silicon nitride charge trap elements) that are vertically spaced apart from each other. The discrete memory elements {54 or (52, 54)} prevent or reduce charge leakage across memory levels, and thus, can provide extended charge retention time and enhanced device reliability. Furthermore, selective growth of the charge storage material portions 54 simplifies the process and forms wider gate length matched charge storage material portions 54. Furthermore, the selective growth forms “mushroom” shaped contoured charge storage material portions 54, which has a more desirable shape for charge storage than “lens” shaped charge storage material portions.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A memory device, comprising:
an alternating stack of insulating layers and electrically conductive layers;
a memory opening vertically extending through the alternating stack and having a lateral undulation in a vertical cross-sectional profile such that the memory opening laterally protrudes outward at levels of the electrically conductive layers; and
a memory opening fill structure located in the memory opening and comprising a vertical stack of blocking dielectric material portions located at the levels of the electrically conductive layers, a vertical stack of discrete memory elements located at the levels of the electrically conductive layers and comprising a respective contoured charge storage material portion having a straight outer cylindrical sidewall and a contoured inner sidewall having an inner cylindrical sidewall segment, an upper annular convex sidewall segment, and a lower annular convex sidewall segment, a tunneling dielectric layer overlying the contoured inner sidewalls of the contoured charge storage material portion, and a vertical semiconductor channel.

2. The memory device of claim 1, wherein the contoured charge storage material portion comprises an outer portion having a first height and an inner portion having a second height greater than the first height.

3. The memory device of claim 1, wherein:
the contoured charge storage material portions comprise a material selected from ruthenium, tungsten, silicon nitride, or silicon; and
the blocking dielectric material portions comprise silicon oxide.

4. The memory device of claim 1, wherein:
the blocking dielectric material portions are discrete blocking dielectric material portions that are vertically spaced apart from each other and interlaced with a vertical stack of dielectric cover material portions along a vertical direction; and
the dielectric cover material portions comprise a material selected from silicon oxynitride, carbon-doped silicon oxynitride, or silicon oxide.

5. The memory device of claim 4, wherein each of the dielectric cover material portions contacts a cylindrical sidewall, an annular top surface segment, and an annular bottom surface segment of a respective insulating layer of the insulating layers of the alternating stack.

6. The memory device of claim 4, wherein each of the dielectric cover material portions comprises an upper annular concave surface segment and a lower annular concave surface segment.

7. The memory device of claim 4, wherein each of the blocking dielectric material portions comprise a respective inner cylindrical sidewall that contacts a straight outer cylindrical sidewall of a respective contoured charge storage material portion, a respective outer cylindrical sidewall, a respective upper annular top surface, and a respective lower annular top surface.

8. The memory device of claim 4, wherein each of the blocking dielectric material portions comprises nitrogen atoms at a variable atomic concentration that decreases with a lateral distance from a cylindrical interface with a respective one of the contoured charge storage material portions.

9. The memory device of claim 1, wherein the blocking dielectric material portions are portions of a dielectric cover layer that are located at the levels of the electrically conductive layers, wherein the dielectric cover layer vertically extends continuously through each electrically conductive layer within the alternating stack.

10. The memory device of claim 9, wherein each of the discrete memory elements comprises a respective tubular charge storage material portion having a straight inner sidewall contacting a straight outer cylindrical sidewall of a respective contoured charge storage material portion.

11. The memory device of claim 10, wherein the tubular charge storage material portions comprise silicon nitride or silicon.

12. The memory device of claim 10, wherein the tubular charge storage material portions comprise a different material than the contoured charge storage material portions.

13. The memory device of claim 1, wherein each of the electrically conductive layers is spaced from a respective neighboring pair of insulating layers of the insulating layers of the alternating stack and from the memory opening fill structure by a respective backside blocking dielectric layer comprising a dielectric metal oxide material.

14. A method of forming a memory device, comprising:
forming an alternating stack of insulating layers and sacrificial material layers over a substrate;
forming a memory opening through the alternating stack, wherein the memory opening has a lateral undulation in a vertical cross-sectional profile such that the memory opening laterally protrudes outward at levels of the sacrificial material layers; and
forming a dielectric cover layer in the memory opening, wherein annular recesses are present in a vertical cross-sectional profile of a physically exposed sidewall of the dielectric cover layer;
forming discrete seed material portions within the annular recesses;
forming a vertical stack of charge storage material portions by selectively growing a charge storage material from physically exposed inner cylindrical sidewalls of the discrete seed material portions while suppressing growth of the charge storage material from physically exposed surfaces of the dielectric cover layer;
forming a tunneling dielectric layer and a vertical semiconductor channel over the vertical stack of charge storage material portions;
forming backside recesses by removing the sacrificial material layers; and
forming an electrically conductive layer within each of the backside recesses.

15. The method of claim 14, wherein the discrete seed material portions comprise a material selected from silicon nitride or silicon.

16. The method of claim 15, wherein the charge storage material comprises a material selected from ruthenium, tungsten, silicon, or silicon nitride.

17. The method of claim 14, wherein the dielectric cover layer comprises a material selected from silicon oxynitride, carbon-doped silicon oxynitride, or silicon oxide.

18. The method of claim 14, wherein:
the backside recesses are formed by removing the sacrificial material layers selective to the dielectric cover layer and the insulating layers; and
backside blocking dielectric layers are formed directly on outer cylindrical surface segments of the dielectric cover layer.

19. The method of claim 14, further comprising:
removing portions of the dielectric cover layer that are exposed in the backside recesses, wherein remaining portions of the dielectric cover layer comprise a vertical stack of discrete dielectric cover material portions contacting a cylindrical sidewall of a respective one of the insulating layers, and outer cylindrical sidewalls of the discrete seed material portions are physically exposed; and
converting the discrete seed material portions into a vertical stack of discrete blocking dielectric material portions by performing an oxidation process, wherein the vertical stack of discrete dielectric material portions are vertically spaced apart from each other and interlaced with the vertical stack of dielectric cover material portions along a vertical direction.

20. The method of claim 19, further comprising forming dielectric metal oxide backside blocking dielectric layers directly on an outer cylindrical sidewall of a respective one of the discrete blocking dielectric material portions.
